(19) United States
(12) Patent Application Publication
(10) Pub. No.: US 2026/0179555 A1
(43) Pub. Date: Jun. 25, 2026

(54) FLOATING-POINT PIXEL VALUES

(71) Applicant: X Display Company Technology Limited, Dublin (IE)

(72) Inventors: Imre Knausz, Fairport, NY (US); Ronald S. Cok, Rochester, NY (US)

(21) Appl. No.: 19/419,299

(22) Filed: Dec. 15, 2025

Related U.S. Application Data
(60) Provisional application No. 63/737,586, filed on Dec. 20, 2024.

(51) Int. Cl. G09G 3/3233; G09G 3/20; H03M 7/24

(52) U.S. Cl. CPC G09G 3/3233; H03M 7/24; G09G 3/2018; G09G 2300/0452; G09G 2300/0809; G09G 2310/0286; G09G 2320/0242; G09G 2320/0626; G09G 2330/021; G09G 2360/16

(57) ABSTRACT

A floating-point display includes pixels. Each pixel can have a pixel memory for storing a pixel value, a light emitter, and a pixel circuit operable to control the light emitter to emit light corresponding to the pixel value. Each pixel value comprises a floating-point value that can be a binary value with a mantissa of M bits and an exponent of E bits. The pixel circuit can output a pulse-width modulation signal of M+E bits to control the light emitter to emit light by sequentially outputting bits of the mantissa in correspondence to the periods of the pulse-width modulation signal shifted in response to the value of the exponent. Different values of the floating-point pixel value can be unique and monotonic, can comprise multiple linear functions, and can increase from zero.

### PRIORITY APPLICATION

This application claims the benefit of U.S. Provisional Patent Application No. 63/737,586, filed on Dec. 20, 2024, the disclosure of which is hereby incorporated by reference herein in its entirety.

### TECHNICAL FIELD

The present disclosure relates to pixel control circuits for light-emitting displays that use temporally variable pulse-width-modulated constant-current control.

### BACKGROUND

Flat-panel displays are widely used to present images and information in graphic user interfaces controlled by computers. Such displays incorporate an array of light-controlling pixels. Each pixel emits or otherwise controls light with a light controller. For example, liquid crystal displays control light emitted from a backlight with a light-blocking liquid crystal at each pixel, organic light-emitting displays emit light from a stack of organic films, and inorganic light-emitting displays emit light from semiconductor crystals.

In binary displays, each pixel controls light to be on at a desired brightness (luminance) or off at a zero brightness. More commonly, pixels control light over a range of luminances (shades of light and dark), from zero to a maximum desired luminance.

The luminance range can be referred to as a gray scale and is defined as a bit depth for a computer-controlled display with pixel values stored as multi-bit binary numbers, for example an eight-bit range (gray scale or bit depth) having 256 different luminance levels or a 12-bit range (gray scale or bit depth) having 4096 different luminance levels. In general, a greater luminance range is preferred to display images with more shades of light and dark in a color or color combination such as white, red, green, or blue.

Depending on the pixel light-control technology, the luminance of a pixel can be controlled by driving a pixel over a range of voltages, over a range of currents, or at a constant power (e.g., at a given voltage and current) for a variable amount of time within an image frame. An image frame is a single image or the amount of time (period) the single image is shown in a video sequence of multiple images. The image-frame period should be short enough that viewers cannot perceive the image as a still image but rather perceives an image motion sequence, as in a video sequence of images. Such temporally modulated signals are often referred to as pulse-width modulation (PWM) signals.

In displays that use inorganic light-emitting diodes (iLEDs) to emit light, the display efficiency is a function of current density in the iLEDs. Thus, modifying the iLED light output by varying the voltage or current density provided to the iLEDs to emit light can reduce power efficiency and can also affect the color of the light. Instead, iLEDs can each be operated at or near an optimum current and voltage to provide a desired efficiency and color of light. To provide apparent gray scale in the display, the displays can be operated using pulse-width modulation (PWM), in which the iLEDs can be turned on (with the optimum power) and off (with zero power) very quickly for a variable amount of time in each image frame-too quickly for a human observer to perceive the flickering and instead perceiving an average luminance for an image.

Pixels that control light with variable time periods can use pulse-width modulation techniques that assign each bit of a multi-bit pixel value using binary digits to a time period having a temporal length corresponding to the relative value of the bit in the multi-bit pixel value. For example, in a four-bit pixel, the least-significant bit can have a temporal period equal to one minimum period and the most-significant bit can have a temporal period equal to eight minimum periods. When all four bits are on, the total time the PWM signal specifies an ON light-emitting luminance signal can equal one plus two plus four plus eight for a total of fifteen times the minimum period. Thus, a four-bit-PWM signal can represent sixteen different luminance values from zero to fifteen. The actual luminance will depend on how brightly the light controller emits light during the ON periods.

Large displays, for example a full-HD, 4K, or 8K display, have a correspondingly large number of pixels and the pixel values associated with each pixel must be communicated to the pixels in the display from an external source with a correspondingly suitable number of bits (specifying the bit depth) for each color of iLED in each pixel. Furthermore, applications such as gaming can require a large image frame rate (a large number of images displayed per second on the display and a correspondingly short image-frame period). The combination of desired bits in each pixel, the number of pixels, and a large image frame rate can result in a large data bandwidth requirement that can be difficult to meet in a flat-panel display, especially a large flat-panel display.

There is a need, therefore, for pixel-control circuits in displays that enable improved gray-scale bit depth, support a large number of pixels, support greater image frame rates, and provide efficient operation with reduced power and bandwidth requirements.

### SUMMARY

According to some embodiments of the present disclosure, among other embodiments, a floating-point display comprises display pixels (pixels), for example provided and interconnected on a display substrate or backplane and responsive to a suitable display controller for displaying an image comprising image pixels. Each pixel can comprise a pixel memory for storing a pixel value, a light emitter or light controller, and a pixel circuit operable to control the light emitter or light controller to emit or control light corresponding to the pixel value when provided with suitable power. (As used herein, the term light controller is used synonymously with light emitter and refers to any component from which light is emitted under the control of the pixel circuit.) For each pixel, the pixel value can be stored in the pixel memory, for example as a binary multi-digit (multi-bit) value, at least partially (or completely) as a floating-point value, for example a floating-point number or a number in a floating-point format or a floating-point numeric expression. As used herein, a binary floating-point pixel value can comprise a mantissa, an exponent, and optionally can comprise additional non-floating-point values or bits. In embodiments, each pixel can comprise multiple pixel memories or single larger pixel memories for storing multiple pixel values (e.g., floating-point pixel values) for corresponding multiple light emitters or multiple light controllers. The multiple light emitters, if present, in each pixel can each emit a different color of light from the other light emitters or light controllers in the pixel, for example red, green, and blue light emitters that correspondingly emit red light, green light, and blue light when provided with suitable power. The pixel circuit can be operable to control the light emitters to emit light corresponding to the pixel values so that each light emitter emits light corresponding to one of the pixel values.

In embodiments of the present disclosure, the floating-point pixel value of a pixel can comprise a mantissa m and an exponent e and the pixel value v representing a desired luminance of an associated light controller or light emitter can be equal to m×2^{e} or is derived from m×2^{e}. In some embodiments, the pixel value v can be equal to m×2^{e} plus an offset or is derived from m×2^{e} plus an offset. As used herein, an offset is a value (a number) and can also be referred to as an offset value. The offset value can be calculated or derived from the floating-point pixel value. In some embodiments, the pixel value v can be equal to (m+k)×2^{(e+j)} or is derived from (m+k)×2^{(e+j)}. In some embodiments, the pixel value v can be equal to (m+k)×2^{(e+j)} plus an offset value or is derived from (m+k)×2^{(e+j)} plus an offset value, where j and k are constants. In embodiments, a floating-point pixel value can comprise at least a mantissa m and an exponent e where m (or a value derived from m) is multiplied by a value equal to a base (such as two) raised to a power equal to e or to a value derived from e.

In embodiments, the offset can (i) the offset can equal (2^{e}−1)×4, (ii) the offset can equal (2^{(e+2)}−4, or (iii) the offset can equal the sum of all values equal to 2⁽ⁿ⁺¹⁾, or (iv) the offset can be derived from or is a combination of the values of (i), (ii), or (iii), where n ranges from one to e and if e is zero the sum is zero.

In embodiments of the present disclosure, the pixels can be disposed in an array of rows and columns on a display substrate. The light emitters can be micro-LEDs, either inorganic or organic, and optionally comprising fractured or separated tethers. In some embodiments, the pixel circuit can be operable to convert the floating-point pixel value to a binary fixed-point pixel value. The fixed-point pixel value can be equal to the floating-point pixel value but does not use a floating-point representation. The binary fixed-point pixel value can be stored in the pixel memory or can be output to the light emitter (or light controller) as it is converted so that the entire binary fixed-point pixel value is never stored as a complete unit in the pixel memory. In embodiments, the pixel circuit can comprise a lookup table operable to convert the floating-point pixel value to an equivalent binary fixed-point pixel value or can comprise an arithmetic circuit operable to calculate an equivalent binary fixed-point pixel value. An arithmetic circuit can be a circuit operable to perform arithmetic, mathematical, or logical operations, or any combination of these, suitable for performing the conversion. Such circuits can comprise digital or analog controllers, CPUs, state machines, adders, shifters, multipliers and the like.

According to embodiments of the present disclosure, a floating-point display can comprise a pixel circuit operable to control a light emitter using pulse-width modulation. In embodiments, the floating-point pixel value comprises a mantissa m having M bits and an exponent e having E bits and the pixel circuit can comprise one or more sequentially accessible memories operable to output sequential bits representing a value of m×2^{e}, 2^{e}, 2^{(e+2)}, (m+k)×2^{e}, (m+k)×2^{e+j}, 2^{e}, 2^{e+j}, 2^{(e+2)}, or any combination of these or derived or responsive to these, where j and k are constants.

In embodiments, the floating-point pixel value comprises a mantissa (m) having M bits and an exponent (e) having E bits, has a maximum value. In embodiments, the pixel circuit can convert the floating-point value to a corresponding pulse-width modulation signal using fewer than log₂((2^{M}−1)×2^{(2\hat{ }E-1)}) storage locations or using fewer than the number of storage locations required to store a maximum possible value of the floating-point pixel value. The maximum value of the floating-point pixel value is the largest value that can be expressed by any combination of bits of the floating-point pixel value. In embodiments, the pixel circuit can comprise an accumulator operable to compute the sum of all values equal to 2\hat{ }⁽ⁿ⁺¹⁾ where n ranges from one to e and the sum is zero if e is zero. In embodiments, the pixel circuit can comprise a counter responsive to a pulse-width modulation (PWM) clock having PWM periods. The PWM clock is a PWM signal having multiple PWM periods (or simply periods). At least some of the multiple PWM periods have a temporal length that is different from others of the multiple PWM periods, for example temporal PWM periods having temporal length values (PWM periods) that are a multiple of two or power of two of other temporal length values (PWM periods). In some embodiments one of the PWM periods is a temporally shortest PWM period that is temporally shorter than any of the other PWM periods and each of the other PWM periods are a unique factor of a power of two longer than the shortest PWM period. for example, the PWM periods can have relative lengths that are a power of two, such as 1, 2, 4, 8, 16, 32, 64, etc. In some embodiments the PWM periods comprise two periods that are both temporally shorter than all of the other PWM periods, for example having relative lengths of 1, 1, 2, 4, 8, 16, 32, 64, etc.

The counter can be operable to count a value that is the exponent e, or a value derived from the exponent e, such as e−1. In embodiments, the counter (or a separate counter) can be operable to count a value that is the number of bits of the mantissa m, for example M or a value derived from M, such as M−1. In embodiments, the counter (or a separate counter) can be operable to count a value that is the number of bits of the exponent e, for example E or a value derived from E, such as E−1. In embodiments, the mantissa m is a binary value comprising bits and the pixel circuit comprises a shift register or equivalent circuit responsive to a pulse-width modulation circuit that sequentially provides the bits in an order corresponding to the places in the binary value and each bit is provided for a time period corresponding to time periods of a pulse-width modulation signal. The shift register can be a serial shift register or a memory (e.g., a pixel memory) controlled by logic that sequentially outputs values stored in the memory, for example at consecutive addresses. In some embodiments, the floating-point pixel value (v) equals m when e is equal to zero and when e is not zero (i) v equals m×2^{e-1} plus an offset equal to 2^{(e+M-1)} or (ii) v equals (m+2^{M})×2^{e-1}. (As used herein, the character × in an equation can indicate a multiplication, multiplied by, or ‘times’.)

In embodiments, the pixel memory does not store a fixed-point pixel value equal to the floating-point pixel value. Instead, the pixel circuit can dynamically generate bits of the fixed-point pixel value in real time as they are needed by the pulse-width modulated signal. Thus, in embodiments of the present disclosure, a pulse-width modulation floating-point conversion circuit (e.g., a PWM floating-point conversion pixel circuit) can comprise a circuit (e.g., a pixel circuit) for receiving a binary floating-point value comprising bits of a mantissa m and exponent e and a circuit for outputting each bit of the mantissa m for a time period corresponding to a pulse-width modulation signal or clock time period. The bits of mantissa m can be sequentially output for time periods corresponding to time periods of the pulse-width-modulation signal. For example, the bits of mantissa m can be sequentially output in place order for time periods corresponding to sequential time periods of the pulse-width-modulation signal in magnitude order. Bits of the mantissa can be shifted by the exponent with respect to corresponding sequential time periods in the PWM clock so that the bits are output for time periods having temporal lengths that are multiplied by 2^{e}. In embodiments, the pixel memory stores fewer than M+2^{E}−1 bits.

In embodiments of the present disclosure, the floating-point pixel value can comprise PWM bits specifying a floating-point value and power bits specifying power levels. (The relative power levels can be the same as relative luminance levels of the light controllers when controlled by the pixel circuit to emit light. “Power level” and “luminance level” can be synonymous herein.) The pixel circuit can be operable to control the light emitter at three or more different power levels (for example including zero or one or both zero and one) in response to the floating-point pixel value. In some embodiments, the floating-point pixel value can comprise a mantissa (m) and an exponent (e) and the light emitter is operable to emit light at m different power levels (or at least me different power levels) in response to the value of the mantissa m. Hence, the maximum value of the mantissa m can specify the number of power levels and the power level output by the pixel circuit to drive a light controller can correspond to the value of the mantissa m for a given floating-point pixel value.

In embodiments, possible floating-point pixel values can specify a monotonic function, can increase from a value of zero (that is one of the floating-point pixel values can be zero or only one of the floating-point pixel values can be zero), and all possible floating-point pixel values can be unique or have a unique value. Ranges of the floating-point pixel value can represent corresponding linear functions having different slopes.

For example, some ranges (or each range) of floating-point pixel values with a common exponent e can specify a different linear function having a different slope.

In some embodiments of the present disclosure the pixel circuit is operable to control the light emitter using pulse-width modulation comprising pulse periods (e.g., different pulse periods having different temporal lengths) and a shortest pulse period is repeated. In embodiments, one of the repeated pulse periods can be used to output light at a reduced luminance corresponding to a power level. In some embodiments, the pixel circuit is operable to control the light emitter using pulse-width modulation comprising pulse periods and is operable to output light at a reduced luminance corresponding to different power levels during the pulse periods, for example different power levels specified by power bits p in the floating-point pixel value or specified by a mantissa m in the floating-point pixel value.

In embodiments, the pixel circuit is operable to directly convert the floating-point pixel value to a pulse-width-modulation signal, for example without ever constructing a complete fixed-point representation of the floating-point pixel value at a single time so that the pixel memory can have only fewer bits than the complete fixed-point representation of the floating-point pixel value.

In embodiments of the present disclosure, a pulse-width modulation system can comprise a component and a control circuit operable to control the component with a pulse-width modulation signal comprising two or more temporal pulses. The two or more temporal pulses in the pulse-width modulation signal can comprise two pulses having the same temporal period. The control circuit can be operable to provide a same amount of power to the component during the two pulses. The control circuit can be operable to provide a different amount of power to the component during one of the two pulses than another of the two pulses. The different amounts of power can be a factor of an integral power of two and one of the different amounts of power can be greater than zero, less than a maximum power (e.g., corresponding to a one value and controlling the light emitter at a designed maximum power), or both greater than zero and less than the maximum power.

In some embodiments of the present disclosure, the floating-point pixel value can comprise a mantissa (m) having M bits and an exponent (e) having E bits and the pixel circuit is operable to (i) control the light emitter using pulse-width modulation having pulse periods, and (ii) control the light emitter to emit light having M different luminances (including zero) during one of the pulse periods. In some embodiments, the M different luminances are less than a relative value of one for the period. In some embodiments, M+1 different luminances ranging from zero to one, and including both zero and one, in different PWM periods. The pixel circuit can be operable to control the light emitter to emit light having M different luminances (including zero) during one, or only one, of the pulse periods. During one or more other PWM periods in the same PWM signal or PWM sequence, the pixel circuit can be operable to control the light emitter to emit light at a relative level of one compared to the M different luminances, which can have relative levels less than one.

In embodiments, of the present disclosure, the number of pulse periods can be 2^{E} or 2^{E}−1, for example when M different luminance levels are used in a period such as when luminance corresponding to the mantissa bits m are controlled at M different luminance levels. In some embodiments, the number of pulse periods can be 2^{(2\hat{ }E-1)} or 2^{(2\hat{ }E-1)}−R, where R is a number of power bits. The pulse periods in a PWM signal or PWM sequence, e.g., for an image frame period, can have different temporal lengths that are relative powers of two. In some embodiments, a PWM signal or PWM sequence can have two PWM periods of equal temporal length that are the shortest PWM periods, and the remaining PWM periods are multiples of two in temporal length of the two shortest PWM periods.

In some embodiments, the pixel circuit is operable to control the light emitter to emit light having M different luminances (including zero) during only one of the pulse periods, and the pixel circuit can be operable to control the light emitter to output light during periods shorter than the only one of the pulse periods when e is greater than zero, for example all of the periods shorter than the only one of the pulse periods when e is greater than zero.

In embodiments of the present invention, the floating-point pixel value comprises a mantissa (m) having M bits, an exponent (e) having E bits, and a power value having R bits where R<M and the pixel circuit is operable to (i) control the light emitter using pulse-width modulation having pulse periods, and (ii) control the light emitter to emit light at one of R different luminances (including zero) during one of the pulse periods.

The only one of the pulse periods can be the period having a relative temporal length corresponding to the value e+1 so that when e=0 the only one of the pulse periods is the shortest pulse period and when e>0, the only one of the pulse periods is the shortest pulse period times (e+1). In some embodiments, both the power bits and the mantissa bits are each controlled to provide a relative luminance level of less than one. In some embodiments, the power bits and the mantissa bits are the same bits in the floating-point pixel value (e.g., R equals M and the power bits are not additional to the mantissa bits).

In embodiments of the present disclosure, a method of operating a floating-point display can comprise providing pixels in the floating-point display. Each pixel can comprise a pixel memory for storing a floating-point pixel value, a light emitter, and a pixel circuit operable to control the light emitter to emit light corresponding to the floating-point pixel value. Methods can comprise receiving a floating-point pixel value for each pixel with the pixel circuit and controlling the light emitter to emit light in response to the floating-point value with the pixel circuit. The pixel circuit can be operable to control the light emitter to emit light using pulse-width modulation. Some embodiments can comprise a pulse-width modulation signal having temporal periods that are powers of two times a minimum pulse period and can comprise controlling the shift register to output the contents of the shift register with the pulse-width modulation signal to control the light emitter (or light controller) to emit light with the pixel circuit.

The floating-point value can comprise a mantissa m and an exponent e and the pixel circuit can be operable to convert the floating-point pixel value to a fixed-point pixel value by storing the mantissa m in a shift register and shifting the mantissa in the shift register in response to the exponent e. In embodiments, the floating-point pixel value can comprise a mantissa m and an exponent e and the pixel circuit can be operable to store the exponent e in a counter and the mantissa m in a shift register and can count the exponent e with the counter and can shift the mantissa m with the shift register in response to the count or can count a number of PWM periods with the counter and apply a counted PWM period to the first mantissa bit and shift remaining bits of the mantissa out of the shift register in response to subsequent PWM periods (e.g., as provided by the PWM clock signals). For example (using zero to reference the first bit of e, m, and the PWM periods, if e is three the zeroth bit of m is output for a time corresponding to the third PWM period. In embodiments, a pulse-width modulation signal can have temporal periods that are powers of two times a minimum pulse period and methods can comprise controlling the counter to count in response to the pulse-width modulation signal and controlling the shift register to output the contents of the shift register with the pulse-width modulation signal to control the light emitter to emit light with the pixel circuit. The pixel circuit can be operable to first count the counter e times and then shift the mantissa m in the shift register to control the light emitter to emit light with the pixel circuit. In some embodiments, the pixel circuit can be operable to set a bit in the shift register having a place location successive to the mantissa m if the exponent e is not zero and to count the counter e−1 times, for example to add 2^{M} to the mantissa value m having M bits.

In embodiments, the pixel circuit directly converts the floating-point pixel value to a pulse-width-modulation signal, e.g., without forming a fixed-point representation of the floating-point value.

According to some embodiments of the present disclosure, a pulse-width modulation system can comprise a first component, a second component, and a control circuit. The control circuit can be operable to control the first component with a first pulse-width modulation signal having a first number of periods and can be operable to control the second component with a second pulse-width modulation signal having a second number of periods. The first pulse-width modulation signal and the second pulse-width modulation signal can have a common temporal length. The first number of periods can be different from the second number of periods. In embodiments, the first component is a first light emitter, and the second component is a second light emitter. The first light emitter can emit light of a first color, and the second light emitter can emit light of a second color different from the first color. Some embodiments can comprise a third component and the control circuit can be operable to control the third component with a third pulse-width modulation signal having a third number of periods. The third pulse-width modulation signal and the first (or second) pulse-width modulation signal can have common temporal length. The third number of periods can be different from the first (or second) number of periods. The first light emitter can emit light of a first color, the second light emitter can emit light of a second color different from the first color, and the third light emitter can emit light of a third color different from the first color and different from the second color. The first light emitter can be a red light-emitting diode operable to emit red light, the second light emitter can be a green light-emitting diode operable to emit green light, and the third light emitter can be a blue light-emitting diode operable to emit blue light.

According to embodiments of the present disclosure, a floating-point display can comprise pixels (e.g., an array of pixels disposed on a display substrate). Each pixel can comprise (i) a pixel memory for storing a first floating-point pixel value and for storing a second floating-point pixel value, (ii) a first light emitter, (iii) a second light emitter, and (iv) a pixel circuit operable to control the first light emitter to emit light corresponding to the first floating-point pixel value and operable to control the second light emitter to emit light corresponding to the second floating-point pixel value. The first floating-point pixel value of each pixel can be or comprise a first floating-point value. The second floating-point pixel value can be or comprise a second floating-point value. In some embodiments, each pixel can comprise a third light emitter, the pixel memory is operable to store a third floating-point pixel value, and the pixel circuit is operable to control the third light emitter to emit light corresponding to the third floating-point pixel value. The third floating-point pixel value can be or comprise a third floating-point value. The first light emitter can be a red light-emitting diode operable to emit red light, the second light emitter can be a green light-emitting diode operable to emit green light, and the third light emitter can be a blue light-emitting diode operable to emit blue light. The pixel circuit (i) can be operable to control the first light emitter using a first pulse-width modulation signal for a first time with a first number of periods and (ii) can be operable to control the second light emitter using a second pulse-width modulation signal for a second time with a second number of periods. The first time can be substantially equal to the second time, e.g., as designed and within manufacturing and circuit performance tolerances. The first number of periods can be different from the second number of periods, e.g., the first and second pulse-width modulation signals can be specified with different numbers of bits. The first light emitter can be a green light-emitting diode operable to emit green light, the second light emitter can be a light-emitting diode operable to emit red or blue light, and the first number of periods can be greater than the second number of periods in respective pulse-width-modulation signals.

According to embodiments of the present disclosure, a multi-color display can comprise pixels (e.g., an array of pixels disposed on a display substrate). Each pixel can comprise (i) a pixel memory for storing a red pixel value, a green pixel value, and a blue pixel value, (ii) a red light emitter, a green light emitter, and a blue light emitter, and (iii) a pixel circuit operable to (a) control the red light emitter to emit red light corresponding to the red pixel value, (b) control the green light emitter to emit green light corresponding to the green pixel value, and (c) control the blue light emitter to emit blue light corresponding to the blue pixel value. The green pixel value can comprise more bits than at least one of the red pixel value or the blue pixel value.

Certain embodiments of the present disclosure provide control circuits and data formats or number representations for pixels in a display that provide improved gray-scale resolution, improved dynamic range, improved light-controller efficiency, and greater frame rates with reduced communication bandwidth and power requirements, especially for large displays. Control circuits and data formats disclosed herein are suitable for inorganic micro-light-emitting diodes and can be applied in an array of pixels in the display.

### BRIEF DESCRIPTION OF THE DRAWINGS

The foregoing and other objects, aspects, features, and advantages of the present disclosure will become more apparent and better understood by referring to the following description taken in conjunction with the accompanying drawings, in which:

FIG. 1 is a schematic diagram of a floating-point display according to illustrative embodiments of the present disclosure;

FIG. 2A is a schematic diagram of a pixel memory for performing a lookup table transform on a fixed-point input value according to illustrative embodiments of the present disclosure;

FIG. 2B is a schematic diagram of a pixel memory for performing a lookup table transform on an input floating-point value according to illustrative embodiments of the present disclosure;

FIG. 2C is a schematic diagram of a circuit for converting a floating-point value to a fixed-point pixel value output with pulse-width modulation according to illustrative embodiments of the present disclosure;

FIG. 3 is a table illustrating a floating-point value having an exponent equal to zero in binary and decimal notation useful in understanding embodiments of the present disclosure;

FIG. 4 is a table illustrating a floating-point value having a two-bit exponent and a two-bit mantissa without a sign bit in binary and decimal notation and the corresponding fixed-point pixel value in decimal and binary notation according to illustrative embodiments of the present disclosure;

FIG. 5 is a schematic diagram of a simplified circuit for converting a floating-point value directly into a pulse-width modulation signal according to illustrative embodiments of the present disclosure;

FIG. 6 is a table illustrating floating-point-pixel-value bits of FIG. 4 sequentially output from lowest to highest bit places using the circuit of FIG. 5 according to illustrative embodiments of the present disclosure;

FIG. 7 is a table illustrating a floating-point value having a two-bit exponent and two-bit mantissa with an offset in binary and decimal notation and a corresponding fixed-point pixel value in decimal and binary notation according to illustrative embodiments of the present disclosure;

FIGS. 8A, 8B, and 8C are different equations defining a same transformation or function converting a binary floating-point pixel value with offset to a fixed-point pixel value corresponding to FIG. 7 according to illustrative embodiments of the present disclosure;

FIG. 9 is a schematic diagram of a simplified circuit for converting a floating-point pixel value into a pulse-width modulation signal using an offset corresponding to the equation of FIG. 8A according to illustrative embodiments of the present disclosure;

FIG. 10 is a schematic diagram of a simplified circuit for converting a floating-point pixel value into a pulse-width modulation signal with an offset corresponding to the equation of FIG. 8B according to illustrative embodiments of the present disclosure;

FIG. 11 is a schematic diagram of a simplified circuit for converting a floating-point pixel value into a pulse-width modulation signal with an offset corresponding to the equation of FIG. 8C according to illustrative embodiments of the present disclosure;

FIG. 12 is a table illustrating a floating-point pixel value having a two-bit exponent and two-bit mantissa in binary notation corresponding to FIG. 7 with a mantissa sequentially output from lowest to highest bit places in a first pulse-width-modulation signal in a first portion of an image frame and an offset sequentially output from lowest to highest bit places in a second pulse-width-modulation signal in a second portion of the image frame according to illustrative embodiments of the present disclosure;

FIG. 13 is a table illustrating a floating-point value having a two-bit exponent and three-bit mantissa in binary and decimal notation and a corresponding fixed-point pixel value in binary and decimal notation according to illustrative embodiments of the present disclosure;

FIG. 14 is a table illustrating a floating-point value having a two-bit exponent and three-bit mantissa in binary notation corresponding to FIG. 13 with a mantissa sequentially output from lowest to highest bit places in a first pulse-width-modulation signal in a first portion of an image frame and an offset sequentially output from lowest to highest bit places in a second pulse-width-modulation signal in a second portion of the image frame according to illustrative embodiments of the present disclosure;

FIG. 15 is a table illustrating a floating-point value having a three-bit exponent and two-bit mantissa in binary and decimal notation and a corresponding fixed-point pixel value in binary and decimal notation according to illustrative embodiments of the present disclosure;

FIG. 16 is a table illustrating a floating-point value having a three-bit exponent and two-bit mantissa with an offset in binary notation corresponding to FIG. 15 with a mantissa sequentially output from lowest to highest bit places in a first pulse-width-modulation signal in a first portion of an image frame and an offset sequentially output from lowest to highest bit places in a second pulse-width-modulation signal in a second portion of the image frame according to illustrative embodiments of the present disclosure;

FIG. 17 is a table illustrating a floating-point value having a three-bit exponent and three-bit mantissa in binary and decimal notation and a corresponding fixed-point pixel value in binary and decimal notation according to illustrative embodiments of the present disclosure;

FIG. 18 is a table illustrating a floating-point value having a three-bit exponent and three-bit mantissa in binary notation corresponding to FIG. 17 with a mantissa sequentially output from lowest to highest bit places in a first pulse-width-modulation signal in a first portion of an image frame and an offset sequentially output from lowest to highest bit places in a second pulse-width-modulation signal in a second portion of the image frame according to illustrative embodiments of the present disclosure;

FIG. 19 is a schematic diagram of a simplified circuit for outputting the offset of a floating-point value into a pulse-width modulation signal according to illustrative embodiments of the present disclosure;

FIG. 20 is a schematic diagram of a simplified circuit for directly outputting the offset of a floating-point value into a pulse-width modulation signal without forming bits of a complete fixed-point offset value according to illustrative embodiments of the present disclosure;

FIG. 21 is a schematic diagram of a simplified circuit for alternating controlling the output of a floating-point pixel value mantissa and controlling the output of a floating-point pixel value offset into a pulse-width modulation signal in two temporal portions of an image frame according to illustrative embodiments of the present disclosure;

FIG. 22 is a table illustrating a floating-point value having a two-bit exponent and two-bit mantissa in binary and decimal notation and a corresponding fixed-point pixel value for a transform different from that of FIG. 7 computed with an offset in binary and decimal notation according to illustrative embodiments of the present disclosure;

FIG. 23 is a table illustrating a floating-point value having a two-bit exponent and three-bit mantissa in binary and decimal notation and a corresponding fixed-point pixel value computed with an offset in binary and decimal notation according to illustrative embodiments of the present disclosure;

FIG. 24 is a table illustrating the floating-point value having a two-bit exponent and two-bit mantissa in binary and decimal notation computed without an offset and a corresponding fixed-point pixel value according to illustrative embodiments of the present disclosure;

FIG. 25A is a pseudo-code specification for computing the value of the transformation with an offset as illustrated in FIGS. 22 and 23 according to illustrative embodiments of the present disclosure;

FIG. 25B is a pseudo-code specification for computing the value of the transformation without an offset as illustrated in FIG. 24 according to illustrative embodiments of the present disclosure;

FIG. 26A is a schematic diagram of a simplified circuit for calculating the exponent e for the transformation illustrated in FIGS. 22-25b according to illustrative embodiments of the present disclosure;

FIG. 26B is a schematic diagram of a simplified circuit for calculating the offset for the transformation illustrated in FIGS. 22, 23 and 25a according to illustrative embodiments of the present disclosure;

FIG. 27 is a schematic diagram of a simplified circuit for implementing the transformation of FIG. 24 and equation of FIG. 25b according to illustrative embodiments of the present disclosure;

FIG. 28 is a table illustrating a floating-point value having a two-bit exponent and two-bit mantissa in binary notation corresponding to FIGS. 24 and 25b with a mantissa sequentially output from lowest to highest bit places with a pulse-width-modulation signal according to illustrative embodiments of the present disclosure;

FIG. 29 illustrates floating-point pixel values comprising an exponent, a mantissa, and power bits according to illustrative embodiments of the present disclosure;

FIG. 30 illustrates a driver-control circuit for the floating-point pixel value of FIG. 29 according to illustrative embodiments of the present disclosure;

FIGS. 31A and 31B are tables illustrating the floating-point pixel values with power bits of FIG. 29 having a two-bit exponent, two-bit mantissa, and two power bits in binary and decimal notation computed without an offset according to illustrative embodiments of the present disclosure;

FIGS. 32A and 32B are tables illustrating the floating-point pixel values with power bits of FIG. 29 having a two-bit exponent, two-bit mantissa, and two power bits in binary and decimal notation computed with an offset according to illustrative embodiments of the present disclosure;

FIGS. 33A, 33B, and 33C timing diagrams of PWM periods with offsets corresponding to the tables of FIGS. 32A and 32B according to illustrative embodiments of the present disclosure;

FIG. 34 is a table illustrating floating-point pixel values without power bits having a two-bit exponent and two-bit mantissa in binary and decimal notation computed without an offset according to illustrative embodiments of the present disclosure;

FIG. 35A is a table illustrating floating-point pixel values with repeated step values for e=1 but without separate power bits and having a two-bit exponent and two-bit mantissa in binary and decimal notation where the mantissa values are also power bits according to illustrative embodiments of the present disclosure;

FIG. 35B is a table equivalent to FIG. 35A with PWM periods shifted by two periods to multiply by four according to illustrative embodiments of the present disclosure;

FIG. 36A is a table illustrating floating-point pixel values without repeated step values for 3=1 and without separate power bits having a two-bit exponent and two-bit mantissa in binary and decimal notation where the mantissa values are also power bits according to illustrative embodiments of the present disclosure;

FIG. 36B is a diagram equivalent to FIG. 36A with showing equivalent PWM periods scaled by a factor of four according to illustrative embodiments of the present disclosure;

FIG. 37 is a flow diagram showing illustrative embodiments of the present disclosure corresponding to FIG. 5;

FIG. 38 is a flow diagram showing illustrative methods of the present disclosure corresponding to FIGS. 9-11;

FIG. 39 is a flow diagram showing illustrative methods of the present disclosure corresponding to FIGS. 27 and 28;

FIG. 40 is a flow diagram showing illustrative methods of the present disclosure corresponding to FIGS. 29-31B;

FIG. 41 is a flow diagram showing illustrative methods of the present disclosure corresponding to FIGS. 30 and 34; and

FIG. 42 is a pulse-width modulation timing diagram for four-bit and three-bit PWM signals having a common image frame according to illustrative embodiments of the present disclosure.

Features and advantages of the present disclosure will become more apparent from the detailed description set forth below when taken in conjunction with the drawings, in which like reference characters identify corresponding elements throughout. In the drawings, like reference numbers generally indicate identical, functionally similar, and/or structurally similar elements.

### DETAILED DESCRIPTION OF CERTAIN EMBODIMENTS

Certain embodiments of the present disclosure provide a display comprising display pixels (also referred to herein as pixels) that each output light in response to a pixel value, for example a value associated with an image pixel and specifying the luminance of a display pixel displaying the image pixel. The display can be a floating-point display, and the pixels can be arranged in an array on a display substrate and controlled using active-matrix control methods for loading rows of pixel values at a time on separate column lines. The floating-point display can have reduced data bandwidth requirements by using pixel values specified in a floating-point format. A display controller can receive floating-point pixel values corresponding to an image from an external source and communicate the received floating-point values to the array of pixels where the floating-point pixel values can be stored and then displayed.

The human visual system has a remarkable ability to perceive light over a great range of luminances. For example, the eye can respond to light as dim as 10⁻⁶ cd and as bright as 10⁵ cd or can even detect a single photon. However, to perceive such a range, the human eye must be adapted to the ambient illumination in the environment. A display that provides good performance in a dark environment or with dark images and good performance in a bright environment or with bright images must likewise emit light over a large luminance range. Moreover, the response of the human visual system and the human eye to light is highly non-linear. Small changes in luminance (an amount of light) can be detected by the human eye in dark environments (or in dark images) but not in bright environments (or for bright images). Thus, a display should provide small changes in luminance for dim luminance levels and can provide larger changes in luminance for bright luminance levels to avoid contouring (visible luminance changes in a desired continuous gray scale). Hence, a pixel value specifying a linear range of luminance values can require a large number of bits to provide small luminance changes for dark images and a suitably large luminance range for the display. Such a linear range would be efficient for relatively small pixel luminance values (providing a good gray scale for dark scenes) but can be inefficient at relatively large pixel luminance values (because the eye cannot detect small luminance changes in bright scenes). For example, a 4k display (2048 rows by 4096 columns with three colors with 16 bits/light-emitter value) can require 50,331,648 bytes (each 8 bits) of information to specify luminance for each light emitter in an image. At a 120 Hz frame rate, this many data (>48 Gb/sec) can be very difficult to transmit over a flat-panel substrate so alternative solutions are desirable. Furthermore, 16 bits is generally considered an inadequate number of bits for a linear pixel value.

To avoid such inefficient encoding of pixel values in an image (e.g., in film, in a digital camera, or in a digital display), pixel values are typically transformed to a non-linear luminance range for output, for example using a gamma function. In a digital system, this conversion can be performed by a lookup table, arithmetic logic circuits, or with a non-linear light-controller driver. However, inorganic light-emitting diodes (iLEDs) operate most efficiently at a given current and voltage so that iLED displays controlling iLEDs using variable voltages or currents are inefficient and can use more power than desired. To operate more efficiently, iLED displays can operate using pulse-width modulation (PWM), in which pixel iLEDs are operated at a constant current and voltage but for variable amounts of time in each image frame (the time during which a single image is displayed, equal to a frame period) to provide a gray scale (apparently variable luminance). If the amounts of time (PWM periods) are fast enough, a human observer will perceive a luminance equal to the amount of light emitted by the iLED over the image frame period.

The different amounts of time in each period of a pulse-width modulation system are typically specified as powers of two times a minimum pulse period (limited by the display electronics performance, the frame period, and the frame rate), for example the powers of two can include 1, 2, 4, 8, 16 ... for as many pulse periods as are desired and requiring a bit for each pulse period specifying an OFF or an ON signal for the pulse period. A binary pixel value having N bits can specify 2^{N} values (including zero) and the non-zero values specify the respective pulse periods that are turned ON during an image frame to determine the pixel luminance for the image frame. As noted above, sufficient lower-value bits (having a lower place value in the pixel value) are needed to avoid contouring in dark portions of an image (because the human eye is sensitive to small luminance changes in the dark portions) but are unnecessary to avoid contouring in bright portions of an image (because the human eye is not as sensitive to small luminance changes in the bright portions). Hence, to provide a pixel value for a display using conventional pulse-width modulation to control light output that specifies both sufficiently small luminance changes for dim pixel values and sufficient luminance range for bright pixel values requires many bits. The many bits can require a high-bandwidth backplane for loading pixel values with many bits into the pixels in the array or a complex or large circuit to convert the pixel value to a suitable PWM pixel of many bits. This is difficult or impossible for a conventional high-resolution thin-film flat-panel display backplane, because the thin-film transistors are large and relative low performance and therefore require a large area on the backplane for the circuit and pixel value storage, limiting the pixel density on the backplane.

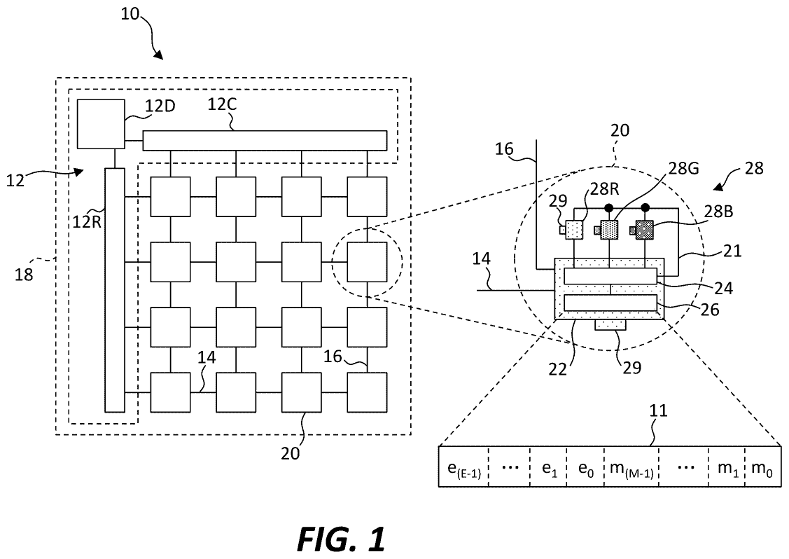

According to embodiments of the present disclosure and as shown in FIG. 1, a floating-point display 10 having an array of pixels 20, each comprising non-native micro-transfer-printed iLEDs 28 and a pixel controller 22 that receives and stores pixel values and controls iLEDs 28 to emit light in response to the pixel values can provide a power-efficient display with increased pixel resolution, display size, and image-frame rate with decreased data bandwidth requirements by specifying pixel values as floating-point pixel values 11 (e.g., pixel values in a floating-point format) and using small and fast circuits (e.g., monocrystalline silicon circuits) in pixel controller 22 to control iLEDs 28 to emit light corresponding to floating-point pixel values 11.

Floating-point pixel values 11 can comprise multiple binary bits that specify a mantissa m and an exponent e in which the mantissa (or a value derived from or incorporating mantissa m) is multiplied by a value equal to a base value (e.g., two for binary pixel values) raised to a power equal to the exponent (e.g., m×2^{e}) (or a value derived from or incorporating exponent e). Floating-point pixel values 11 can also include additional bits that specify other values defining a light-controller 28 luminance. According to embodiments of the present disclosure, floating-point pixel value 11 can be any value that at least multiplies a value derived from floating-point pixel value 11 by a value that is raised to an exponent derived from floating-point pixel value 11 and can include other arithmetically combined values or that specify other values defining a value or luminance for light-controller 28.

Non-native pixel controllers 22 and iLEDs 28 can be photolithographically constructed on corresponding source wafers and transfer printed to a display substrate 18. FIG. 1 illustrates a floating-point display 10 comprising pixels 20. Pixels 20 can be disposed in an array on display substrate 18 and connected in rows with row wires 14 connected to a row controller 12R and connected in columns with column wires 16 connected to a column controller 12C. Row controller 12R can control pixels 20 through row wires 14 and column controller 12C can control pixels 20 through column wires 16, for example using active-matrix methods. Row controllers 12R and column controllers 12C can be connected, for example, to a display interface 12D. Row controllers 12R, column controllers 12C, and display interface 12D can comprise display controller 12 and can comprise one or more integrated circuits, for example disposed on (or off) display substrate 18 external to a display area comprising pixels 20 and connected to row wires 14 and column wires 16. Row wires 14 and column wires 16 can be formed on display substrate 18 and row controllers 12R and column controllers 12C can be formed on and native to display substrate 18 or row controllers 12R and column controllers 12C can be disposed on and non-native to display substrate 18.

As shown in the larger inset of FIG. 1, each pixel 20 can comprise a pixel controller 22 and one or more light controllers 28, such as liquid crystals (LCs), organic light-emitting diodes (OLEDs), or inorganic light-emitting diodes (iLEDs), connected with pixel wires 21. Pixel controller 22 can be operable to control light emission from light controllers 28. Light controllers 28 are also referred to herein as iLEDs 28 that can operate most power-efficiently at a constant current and voltage over time (but are not limited to iLED 28 embodiments). As shown in FIG. 1, pixel 20 comprises three iLEDs 28: red iLED 28R that can emit red light when provided with suitable electrical voltage and current, green iLED 28G that can emit green light when provided with suitable electrical voltage and current, and blue iLED 28B that can emit blue light when provided with suitable electrical voltage and current. Pixel controller 22 together with red iLED 28R, green iLED 28G, and blue iLED 28B can comprise a full-color active-matrix pixel 20. iLEDs 28 can be micro-iLEDs 28 disposed on display substrate 18. Pixel controller 22 and iLEDs 28 can be disposed or adhered directly on display substrate 18, as shown in FIG. 1, or on a pixel substrate, by micro-transfer printing to form a pixel module that can be disposed on display substrate 18 that can be tested as a pixel 20 prior to assembly. iLEDs 28 and pixel controller 22 can comprise broken (e.g., fractured) or separated tethers 29 as a consequence of micro-transfer printing them from corresponding iLED 28 or pixel controller 22 source wafers.

Pixel controller 22 can comprise a pixel circuit 24 and a pixel memory 26. Pixel circuit 24 can be a digital circuit or an analog circuit, or a hybrid circuit comprising digital and analog circuit components. Pixel circuit 24 can be operable to receive data signals (e.g., row-select and column-data signals on row wires 14 and column wires 16, respectively) from display controller 12, store the received signals in pixel memory 26, and then control iLEDs 28 to emit light in response to the stored data signals, e.g., using interface circuits that can communicate with display controller 12, pixel memory 26 read and write circuits, and iLED 28 driver circuits. Any one or combination of iLEDs 28 and pixel controller 22 can be micro-transfer printed from a corresponding source wafer to display substrate 18 or a pixel substrate that is subsequently assembled onto display substrate 18 and can therefore be non-native to display substrate 18. The data signals can comprise pixel values, as well as other control or timing signals, such as pulse-width modulation period signals.

Pixel memory 26 can be or comprise a digital or analog storage circuit, for example one or more of or multiple ones of an SRAM, DRAM, latch, register, shift register, counter, or the like operable to store one or more floating-point pixel values 11, for example one floating-point pixel value 11 for each iLED 28. Floating-point pixel values 11 can specify the amount of light to be output using iLEDs 28 by pixel circuit 24. Each floating-point pixel value 11 can comprise a mantissa (m), having M bits, also known as a significand and representing significant digits in the floating-point value and an exponent (e) having E bits, e.g., each as bits in a multi-bit binary value. The pixel 20 luminance corresponding to floating-point pixel value 11 can be relatively equal to, derived from, or related to (m×2^{e}), where 2 is the base of the floating-point value, and corresponding to conventional binary digits in a binary digital computer. The bits of the floating-point value can be stored as and referred to in any useful arrangement but, as shown in FIG. 1 and as used herein, mantissa m comprises bits m₀ through m_{(M-1)} and exponent e comprises bits e₀ to e_{(E-1)} and can be received in any order and stored in any order in one or more portions of pixel memory 26. E and M are independent and each can be larger or smaller than the other. As used herein and in embodiments, the floating-point value has no sign, as the floating-point value specifies a positive amount of light (luminance) to be emitted from iLEDs 28.

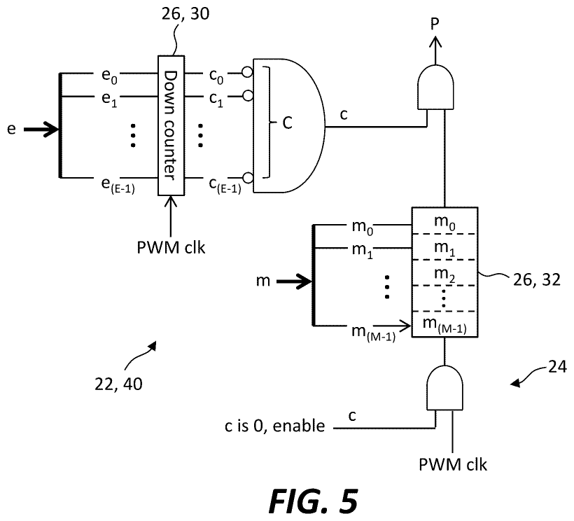

As shown in the smaller inset of FIG. 1, the bits of mantissa m and of exponent e can each be stored in sequentially accessible and optionally separate storage locations in pixel memory 26, for example having adjacent addresses in a memory or sequentially connected storage locations in a register, such as a shift register. Pixel memory 26 is therefore operable to store binary values corresponding to floating-point pixel value 11. Pixel memory 26 can comprise an exponent counter 30 and a mantissa shift register 32 (as discussed below with respect to FIG. 5). Floating-point pixel value 11 can be received from display controller 12 by pixel circuit 24 as bits in parallel or can be received as sequential bits and can be stored in pixel memory 26 in parallel or sequentially. As those knowledgeable in circuit design, a variety of circuits can be designed to implement pixel controller 22, pixel circuit 24, and pixel memory 26. The ellipses in the smaller inset of FIG. 1 indicate additional bits (if any) between the indicated bits and the largest bit (having the largest place value) of m or e, respectively, in pixel memory 26.

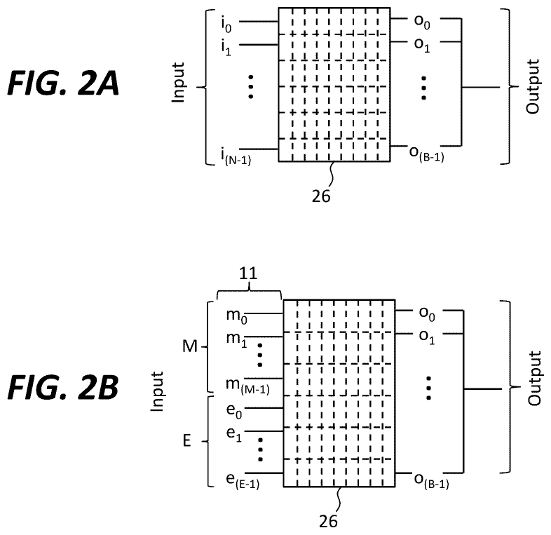

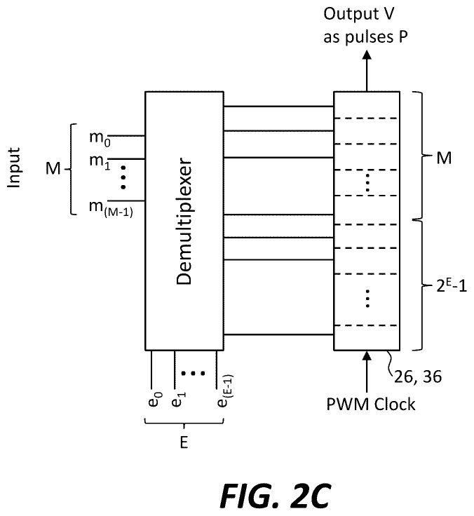

FIG. 2 illustrates various bit requirements for various embodiments. In FIG. 2A, a simple lookup table (e.g., pixel memory 26) has N inputs for input values having bits io to i_{(N-1)}. The bit depth is specified by the number of bits B necessary to provide adequate range. Using the (rather inadequate) 16 bits of the example above, and an 8-bit input value, pixel memory 26 requires 2⁸×16=4096 bits. A pixel memory 26 of this size can be difficult and expensive to include in every pixel controller 22 in every pixel 20. FIG. 2B illustrates the memory requirements for a floating-point pixel value 11 having a mantissa m of M bits and exponent e of E bits. Each input value, therefore, has at least E+M bits. The output can have whatever range and number of bits is desired. Using E=2 and M=6 (so the input pixel value has 8 bits), the maximum value of the input is (2⁶−1)×(2^{(2\hat{ }E-1)}) or 63×2³=504, a nine-bit value in a fixed-point format. Pixel memory 26 then requires 256×9 or 2304 bits. The number of bits stored in pixel memory 26 for each floating-point pixel value 11 in each pixel 20 depends greatly on the range of the exponent, as that value provides the increased range of the floating-point pixel value 11. In any case, for this example pixel memory 26 is even larger than is required for the 16-bit maximum output of FIG. 2A, in order to provide the increased range.

FIG. 2C illustrates embodiments in which a floating-point pixel value 11 of (m×2^{e}) is directly loaded in fixed-point format into a pixel memory 26 fixed-point shift register 36 having sufficient bits to store the resulting fixed-point pixel value v (e.g., having up to M+2^{E}−1 bits). Mantissa M is presented to a circuit (e.g., a demultiplexer circuit) operable to load the M bits into the appropriate M locations in pixel memory 26 in response to exponent e. Memory locations that are not loaded with one of the M bits in mantissa m are set to zero. The bits in pixel memory 26 can then be sequentially accessed (e.g., by shifting) in response to the PWM clock to output the corresponding bits for the corresponding PWM period and output, for example to an iLED 28 driver. This design requires less memory than the embodiments of FIGS. 2A and 2B but still requires a complete representation of floating-point pixel value 11 in a fixed-point format (in pixel memory 26).

The examples provided in FIGS. 2A-2C and elsewhere in the disclosure generally have many fewer bits than would be necessary for a practical implementation so that the information presented is readily understood and the Figures are of manageable size.

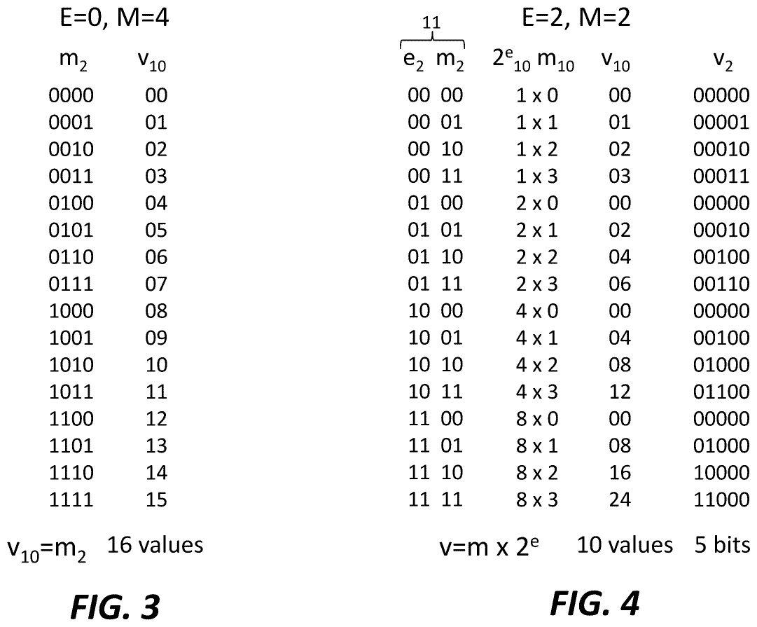

FIG. 3 illustrates bits in a floating-point pixel value 11 having a mantissa of m with four bits M and an exponent e of zero bits (shown in base 2 on the left) and the equivalent value v in base 10 on the right. Because exponent e is zero, mantissa m is equivalent to a four-bit binary value, as shown with value v specifying sixteen different values (including zero). Thus, FIG. 3 simply shows the values of a 4-bit binary number and the decimal equivalent. FIG. 4 illustrates bits in a floating-point pixel value 11 having a mantissa of m with two bits M and an exponent e of two bits E (shown in base 2 on the left) and the equivalent value v in base 10 and in base 2 on the right. The number of bits required to express the equivalent largest value v (m×2^{e} or 3×8 equal to 24) is five bits. The multiplication of m×2^{e} is shown in base 10 vertically in the center of FIG. 4. Because some of the values (e.g., where m is zero) are repeated, the number of distinct values in floating-point pixel value 11 input is ten. A mantissa with more bits in m (having a larger M) can specify more distinct values (e.g., M=8, 10, or 12) and an exponent e with more bits (having a larger E) provides a greater range. Two bits for each of e and m (E=M=2 or 3) are used in the examples for clarity and simplicity and to reduce the size of the figures. In practice M is likely to be at least eight and E at least four, five, or six to provide sufficient bits to avoid perceptible contouring in dark portions of an image and express sufficient luminance range for bright portions of an image.

The simple block diagram designs of FIGS. 2A-2C require a relatively large amount of pixel memory 26, including one or more fixed-point representations of an output value v derived from an input floating-point pixel value 11 and used to control the ON or OFF status for each PWM period. FIG. 5 illustrates embodiments in which a fixed-point representation of input floating-point pixel value 11, is not necessary or is not stored in pixel memory 26.

FIG. 5 is a simplified schematic block diagram illustrating the function of pixel controller 22 for the example of FIG. 4. FIG. 5 excludes most timing and control signals to clarify the function of pixel controller 22 outputting a PWM signal responsive to floating-point pixel value 11 without a fixed-point representation of floating-point pixel value 11, thereby reducing storage requirements of pixel controller 22. As shown in FIG. 5, an input floating-point pixel value 11 comprising a mantissa m having M bits and an exponent e having E bits is provided to pixel controller 22, for example serially or in parallel by display controller 12 (not shown in FIG. 5). The heavy dark lines in FIG. 5 illustrate a bus of multiple wires, for example signal wires carrying E bits of exponent e or M bits of mantissa m. The exponent e bits are loaded into an exponent counter 30 and the mantissa m bits are loaded into mantissa shift register 32 and can both be portions of pixel memory 26. The remainder of the circuit can be a part of pixel circuit 24. The output of exponent counter 30 has C bits c that, when inverted and combined with an AND function equals one (or a positive voltage or TRUE value) when c is zero and indicates that exponent counter 30 has counted down to a zero value, e.g., has counted the value of exponent e in response to a PWM clock. In operation, the PWM clock (either provided externally, for example by display controller 12 or generated internally in pixel controller 22) having temporal periods that have lengths that are a power of two times a minimum period (corresponding to a one bit of the mantissa if e is zero) triggers exponent counter 30 and causes exponent counter 30 to count down with ever slower cycles (corresponding to increasing PWM periods).

If e is zero, count c is zero and the AND gates receiving the c signal are enabled. The first bit of the mantissa is output as pulse P until the PWM clock causes pixel memory 26 to output the next bit of mantissa m. The PWM clock periods can be successively larger by a factor of two and the bits of mantissa m can be disposed in pixel memory 26 in sequentially larger order to successively output with successively longer PWM clock periods. Pixel memory 26 can be or comprise, for example, a mantissa shift register 32, a register whose outputs are successively accessed by the PWM clock, for example using a multiplexer, or a memory whose bits are successively addressed so that each successively output bit of m is output for twice the previous PWM period in response to the PWM clock. Those knowledgeable in the digital circuit design arts will understand that many different circuits can be used for pixel controller 22 and such designs are included herein.

If e is greater than zero, count c is not initially zero and the AND gates receiving the c signal are disabled so that pulse P output is zero until exponent counter 30 counts down in response to successive PWM clock signals and equals zero. At the same time, access to mantissa shift register 32 (e.g., with the PWM clock) is inhibited so that the bits of mantissa m are not accessed or shifted. The first bit of the mantissa is output when the PWM clock enables pixel memory 26 and pulse P. The period of the PWM signal associated with the first bit of mantissa m will be the period corresponding to the count of e. Thus, if e is one, the first pulse period has an output of zero and the remaining PWM pulses will have temporal periods that sequentially correspond to mantissa bits m. If e is two, the first two pulse periods have an output of zero and the remaining PWM pulses will sequentially correspond to the mantissa m bits, and so on. Thus, the bits of mantissa m are delayed by the PWM periods used to count exponent counter 30 e times and are increased in temporal length by the corresponding PWM periods. The sequentially output bits corresponding to the sequential PWM periods are sequentially shown in the v₂ (value in base 2 or binary notation) column of FIG. 4, from right to left. The first e bits result in a zero P value and correspond to the first e PWM periods and the following m bits are output for periods corresponding to the following PWM periods, thus temporally multiplying mantissa m by e. The pulse output P can control or drive an iLED 28 at a constant current and voltage when pulse P is one (corresponding to a mantissa m bit of one).

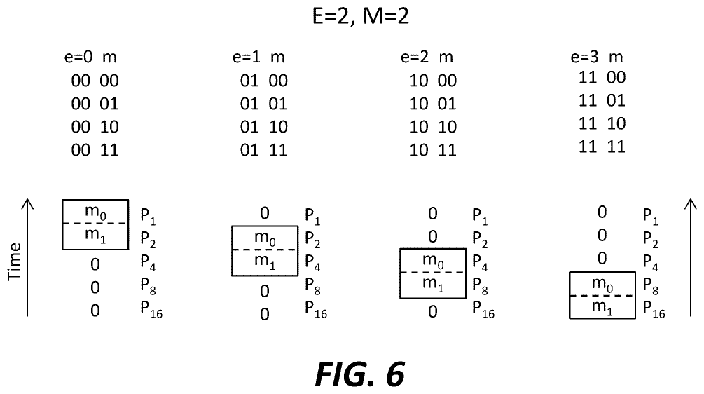

FIG. 6 visually illustrates the output of the PWM bits in correspondence with the PWM pulse periods for each of exponent values 0, 1, 2, and 3 in the circuit of FIG. 5.

Pixel memory 26 can store the M bits of mantissa m (in this case two bits) that are shifted out in the direction shown by the arrow from mantissa shift register 32 in correspondence with the indicated PWM pulse period having a relative temporal length corresponding to the subscript. When e is zero, the M bits of mantissa m are shifted out with the first two pulse periods P₁ and P₂ having relative temporal period lengths of one and two. When e is one, exponent counter 30 counts one, during which pulse period P having a relative temporal period length of one is output as zero followed by the bits of mantissa m with pulse periods two and four. When e is two, exponent counter 30 counts two, during which pulse periods P having a relative temporal period lengths of one and two are output as zero followed by the bits of mantissa m with pulse periods four and eight. When e is three, exponent counter 30 counts three, during which pulse periods P having a relative temporal period lengths of one, two, and four are output as zero followed by the bits of mantissa m with pulse periods eight and sixteen.

The total memory required for pixel memory 26 in FIG. 5 (including exponent counter 30 for storing e and mantissa shift register 32 for storing m) equals E+M bits, for a total of four bits, rather than M+2^{E}−1 or 5 bits as in FIG. 2C (corresponding to the log base 2 of the number of bits required to store a fixed-point representation of the largest possible value equal to log₂((2^{M}−1)*(2²\hat{ }^{E-1)})). If the same function was performed using a lookup table to provide an equivalent linear value v with sufficient bits (a binary fixed-point pixel value), the table would require 16 input rows (equal to 2^{(E+M)}) and five bits for the largest value of 24 for each table entry resulting in a total of 80 bits. Thus, although the logic is more complex with a design such as FIG. 5 (e.g., including exponent counter 30, a sequential access memory such as mantissa shift register 32, and AND gates), the memory requirements are vastly reduced. For a more practical implementation, for example with M=8 and E=4, the total number of bits in a FIG. 5 design is 12 as opposed to 4096(2¹² ) values of 23 bits [calculated as log₂(m×2^{e}) for maximum m equal to 2^{M}−1(=255) and maximum e equal to 2^{E}−1(=15)] each for a lookup table of >90 000 bits, as in embodiments such as FIG. 2B. The FIG. 2C design would require 8+15 or 23 bits for the fixed-point representation of the largest floating-point pixel value 11 with M=8 and E=4. Thus, embodiments such as that of FIG. 5 can significantly reduce the memory requirements of pixel controller 22.

As illustrated in FIG. 4, a floating-point pixel value 11 can express repeated zero values multiple exponent values. For example, and as shown in FIG. 4 for M=E=2, a zero value is encoded four times, and each of a two, four, and eight value is encoded two times or 2×2^{E}−1. Thus, the four-bit pixel value only stores ten unique values, and such redundant encoding can be inefficient. In effect, the mantissa values provide a linear transformation starting at zero with a different slope for each different value of exponent e.

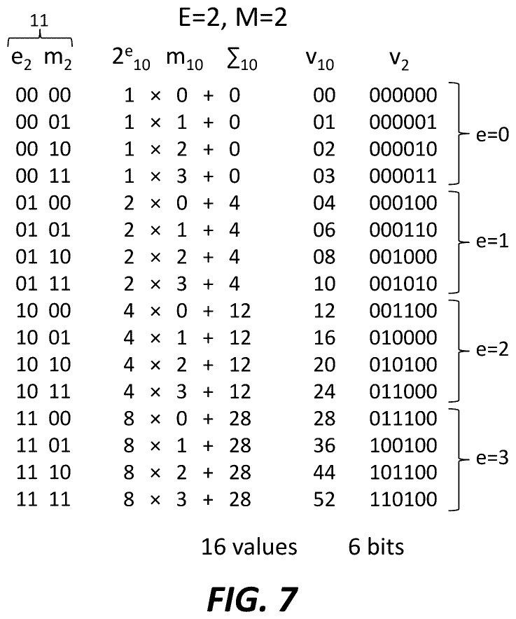

According to some embodiments of the present disclosure, a pixel value can be coded or represented as a floating-point value plus an offset to provide a monotonic transformation (a monotonic function) beginning at zero of a floating-point pixel value 11 to luminance output without any redundant values. The monotonic function can comprise multiple linear portions having different slopes, each linear portion responsive to a different exponent value e. As shown in FIG. 7 for M=E=2, each value of m equaling zero is assigned an offset (shown with the sum sign Σ) that is added to all larger values of m for each value of e. Each possible floating-point pixel value 11 can be unique, so that there are no redundant outputs from the monotonic function. Smaller floating-point pixel values 11 can correspond to linear portions with a smaller slope so that changes in luminance are correspondingly smaller. Larger floating-point pixel values 11 can correspond to linear portions with a greater slope so that changes in luminance are correspondingly larger, thus accommodating the response of the human visual system.

As shown in FIG. 7, when e equals zero, the offset is zero, when e equals one, the offset is four, when e equals two, the offset is 8, and so on, the offset increasing by a factor of two for each subsequent increase in the value of e. The maximum value v output for M=E=2 is 52 requiring six bits, compared to a maximum value of 24 requiring five bits as shown in FIG. 4. Thus, the use of an offset for a floating-point pixel value 11 increases the number of distinct values and decreases contouring when applied to an image, especially for smaller values of floating-point pixel value 11. As in FIG. 4, FIG. 7 illustrates bits in a floating-point pixel value 11 having a mantissa of m with two bits M and an exponent e of two bits E (shown in base 2 on the left) and the equivalent value v in base 10 and in base 2 on the right.

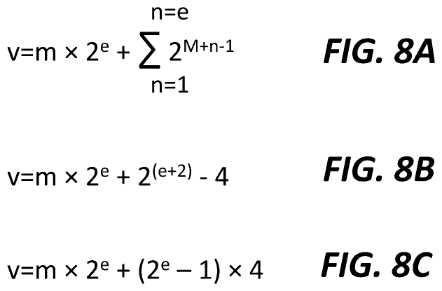

The conversion of floating-point pixel value 11 with an offset into a pixel value for output to an iLED 28 can be done in various ways or can be expressed with different equations or functions, and those knowledgeable in digital design will understand that different embodiments can be designed and are included herein. FIGS. 8A, 8B, and 8C list several different equations specifying the same transformation and corresponding to mathematically equivalent arithmetic computations that can calculate the transformation shown in FIG. 7. Each of these equations can be implemented in digital logic as described in the following Figures.

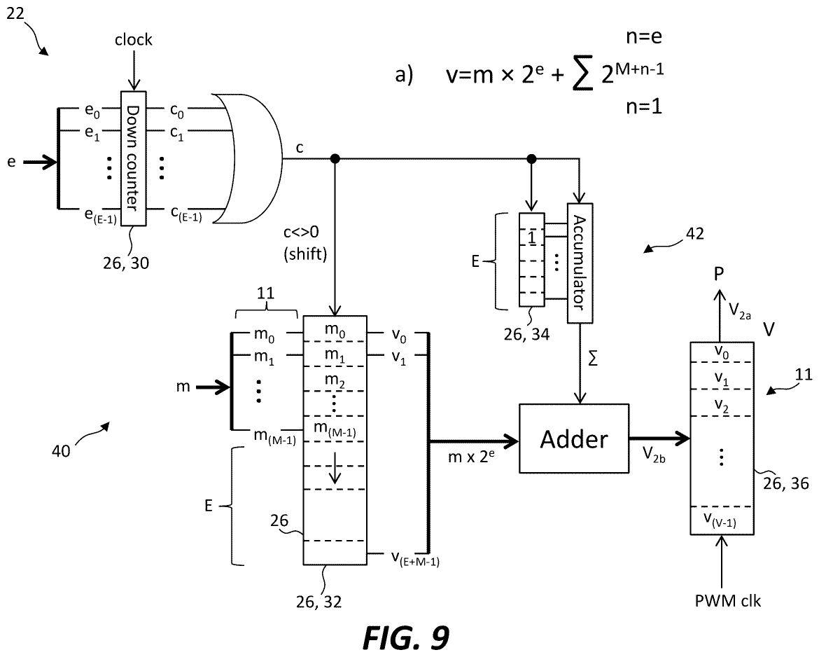

FIG. 9 illustrates a design for calculating equation 8A. As shown in FIG. 9, a floating-point pixel value 11 having a mantissa m of M bits and an exponent e of E bits is loaded into pixel memory 26 comprising mantissa shift register 32 and exponent counter 30. Pixel memory 26 should have at least M+E bits. Mantissa m is loaded into mantissa shift register 32 and e is loaded into exponent counter 30. If e is zero, count (shift) value c is zero and m is output through the adder to a fixed-point shift register 36 that can be shifted out using a PWM clock having successive periods that are powers of two. If e is greater than zero, the count c (shift) value is counted e times with a system clock (not the PWM clock) and shifts m in mantissa shift register 32 (that can be a part of pixel memory 26) to multiply by two for each shift operation. Thus, mantissa shift register 32 will, after e shifts, store a fixed-point representation of m×2^{e}. At the same time an offset shift register 34 is initialized at two and shifted for each count cycle so that if e is one the value in offset shift register 34 is four, increasing by factors of two as the offset value is shifted. This offset register 34 value is accumulated with the accumulator in response to the clock. Thus, the accumulator adds successive powers of two (starting at four) as e is counted in exponent counter 30. After e is counted down, the shifted value of m (now equal to m×2^{e}) is added to the accumulated offset value to produce the transformed value v. The value v can be stored in a fixed-point shift register 36 of pixel memory 26 and can be double buffered as V₂ₐ and V_{2b} so that V₂ₐ is shifted out in response to the PWM clock while V_{2b} is shifted, accumulated, and added as described for V₂ₐ using a system clock so that any time for the construction of fixed-point pixel value v does not delay PWM output in an image frame.

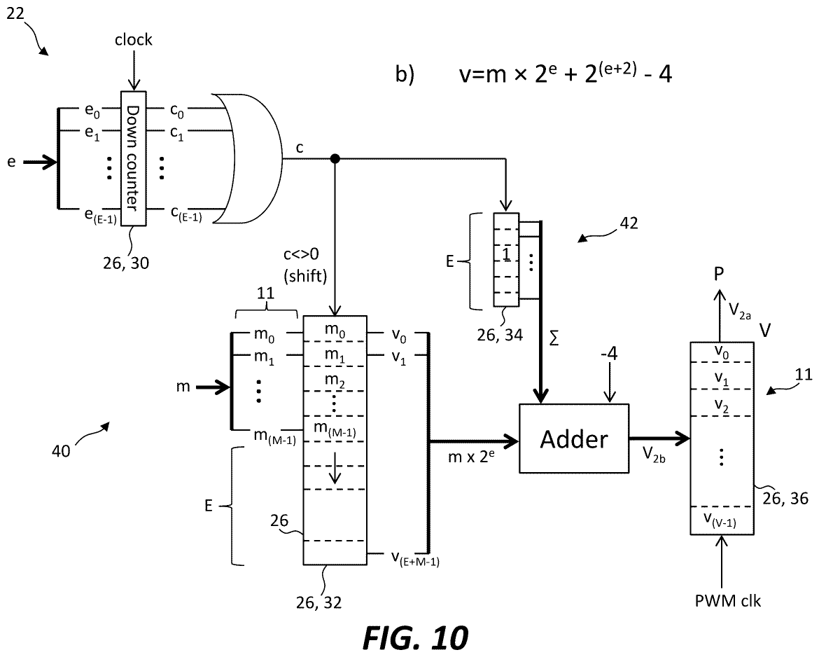

FIG. 10 illustrates a design for calculating equation 8B. As shown in FIG. 10, a floating-point pixel value 11 having a mantissa m of M bits and an exponent e of E bits is loaded into mantissa shift register 32 and exponent counter 30 of pixel memory 26, respectively. Pixel memory 26 should have at least M+E bits. If e is zero, exponent counter 30 value c is zero and m is output through the adder from mantissa shift register 32 to fixed-point shift register 36 that can be shifted out using a PWM clock (having successive periods that are powers of two). If e is greater than zero, exponent counter 30 count value c is counted e times with a system clock (not the PWM clock) and shifts m in mantissa shift register 32-pixel memory 26 to multiply by two for each shift. As with FIG. 9, after the e shifts, mantissa shift register 32 will contain a fixed-point representation of m×2^{e}. At the same time an offset shift register 34 value sigma is initialized at four and shifted for each count cycle so that if e is zero the sigma value in offset shift register 34 is four and if e is one the sigma value in offset shift register 34 is eight, and so on, increasing by factors of two as the offset sigma value in offset shift register 34 is shifted. The offset shift register 34 value sigma is applied to the adder along with a value of (−4). After e is counted down, the shifted value of m (now equal to m×2^{e}) in mantissa shift register 32 is added to the shifted offset value sigma and (−4) to produce the transformed value v. The value v can be stored in a fixed-point shift register 36-pixel memory 26 and can be double buffered as V₂ₐ and V_{2b} so that V₂ₐ is shifted out in response to the PWM clock while V_{2b} is shifted and added as described for V₂ₐ using a system clock. This design does not require an accumulator.

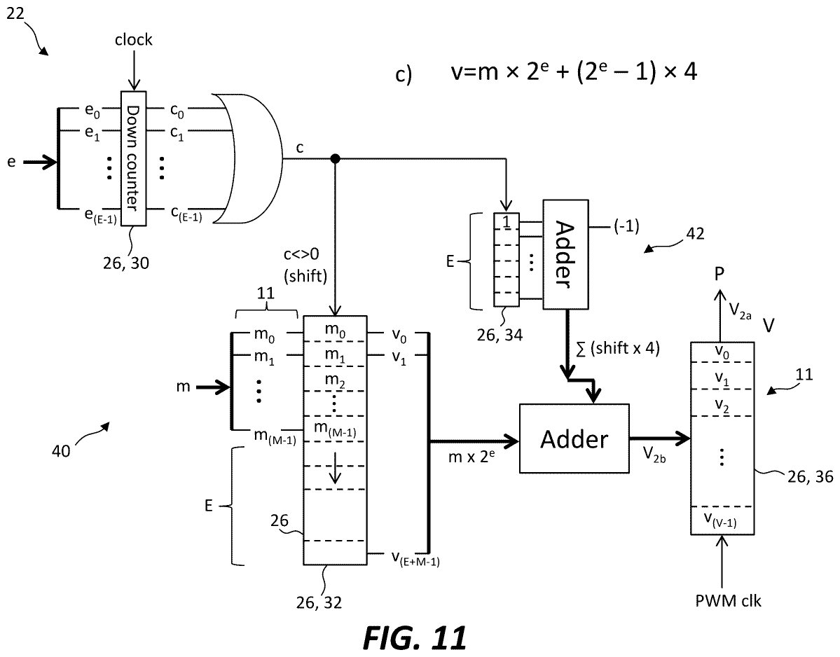

FIG. 11 illustrates a design for calculating equation 8C. As shown in FIG. 11, a floating-point pixel value 11 having a mantissa m of M bits and an exponent e of E bits is loaded into mantissa shift register 32 and exponent counter 30 of pixel memory 26, respectively. Pixel memory 26 should have at least M+E bits. If e is zero, exponent counter 30 count value c is zero and m is output through the adder to fixed-point shift register 36 to form a fixed-point representation of m×2^{e} that can be shifted out using a PWM clock (having successive temporal periods that are powers of two). At the same time, a second adder adds the offset shift register 34 value (initialized to a 1 value equal to 2⁰ ) to a (−1) to sum to zero. The zero is added to the shifted mantissa value in mantissa shift register 32 and loaded into fixed-point shift register 36 of pixel memory 26 where it can be output as a PWM signal in response to the PWM clock. If e is greater than zero, the count c (shift) value is counted e times with a system clock (not the PWM clock) and shifts m in mantissa shift register 32 to multiply by two for each successive shift. At the same time an offset shift register 34 is initialized at one and shifted for each count cycle so that if e is zero the value in offset shift register 34 is one and if e is one the value in offset shift register 34 is two, and so on, increasing by factors of two as the offset value is successively shifted. The offset register 34 value sigma is applied to an adder along with a value of (−1). After e is counted down, the shifted value of m (now equal to m×2^{e}) is added to the offset value sigma shifted by two places (multiplying by four) to produce the transformed value v. The value v can be stored in fixed-point shift register 36 of pixel memory 26 and can be double buffered as V₂ₐ and V_{2b} so that V₂ₐ is shifted out in response to the PWM clock while V_{2b} is shifted and added as described for V₂ₐ with a system clock. This design does not require an accumulator.

The embodiments illustrated in FIGS. 9-11 all use an adder to construct the fixed-point pixel value v (derived from the floating-point pixel value 11 with offset transformation as in FIG. 7) that is subsequently output using a PWM clock from fixed-point register 36. Mantissa shift register 32 also stores a shifted mantissa value m×2^{e} in fixed-point format. The value v can therefore have more bits and require more memory than can be desired in pixel controller 22. Thus, in some embodiments of the present disclosure, the bits of the value v can be sequentially output without ever constructing and storing the entire fixed-point bit sequence of value v (having up to M+2^{E}−1 bits). Moreover, some such embodiments do not require an adder or accumulator, simplifying the circuits needed in pixel memory 26. This can be done in a variety of ways with a variety of circuits.

In one design and according to embodiments of the present disclosure, an image frame is temporally divided into two identical PWM cycles. The first PWM cycle can output mantissa m shifted by the exponent e value equaling m×2^{e} (as in FIG. 5). The second PWM cycle can output the offset value. The human eye can average light output from the two PWM sequences (just as it does for a single PWM cycle that is twice as long). As long as the image frame rate is fast enough (so that the PWM periods are short enough), the individual periods of each PWM sequence cannot be detected by a human observer and the order of the PWM periods is not important. Thus, PWM periods for the output of the mantissa in PWM cycle one and the PWM periods for the output of the offset in PWM cycle two can be done at separate times within a single frame period and the order of the PWM periods (if done at a fast enough frame rate) will not be perceived by a human observer.

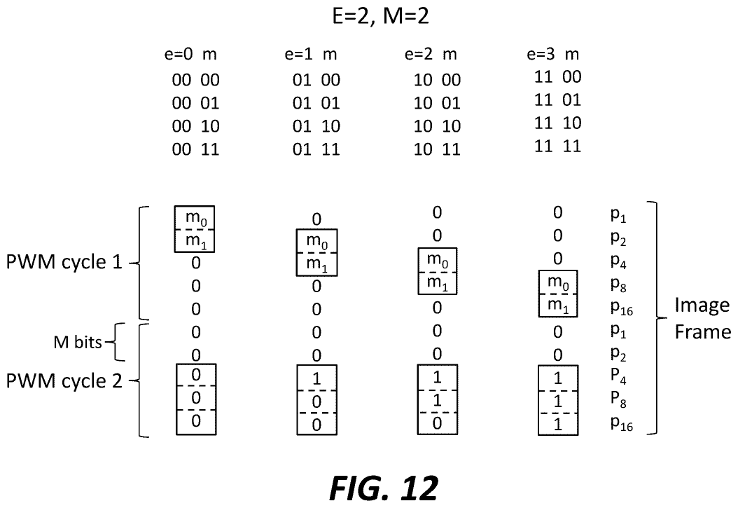

FIG. 12 illustrates a bit sequence for such a design for an exponent e with two bits (E=2) and a mantissa m with two bits (M=2). The upper portion of FIG. 12 shows the possible value of m for each of the possible four values of e (zero through three). The PWM bit periods associated with each of the two PWM signals for an image frame are indicated (p₁ to p₁₆) with the associated bits of the corresponding floating-point pixel value 11. The bits of the mantissa are indicated as m₀ and m₁ with the corresponding PWM signal period (shifted as indicated for the corresponding exponent e value) for the first PWM signal in the first half of the image frame. The offset bits are shown with the second PWM signal and are indicated with ones and zeros, as appropriate and corresponding to the appropriate PWM period (e.g., p₁, p₂, . . . p₁₆) with M initial zero bits of zero (corresponding to the case in which e is zero) and followed by the offset bits (e.g., as illustrated in FIGS. 7 and 8A). The columns of bits as indicated in the lower half of FIG. 12 can be output over time with each bit output for the PWM period indicated.

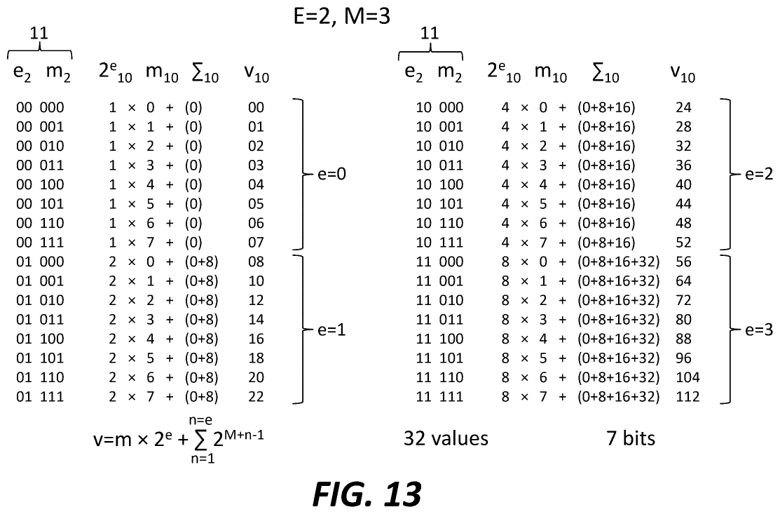

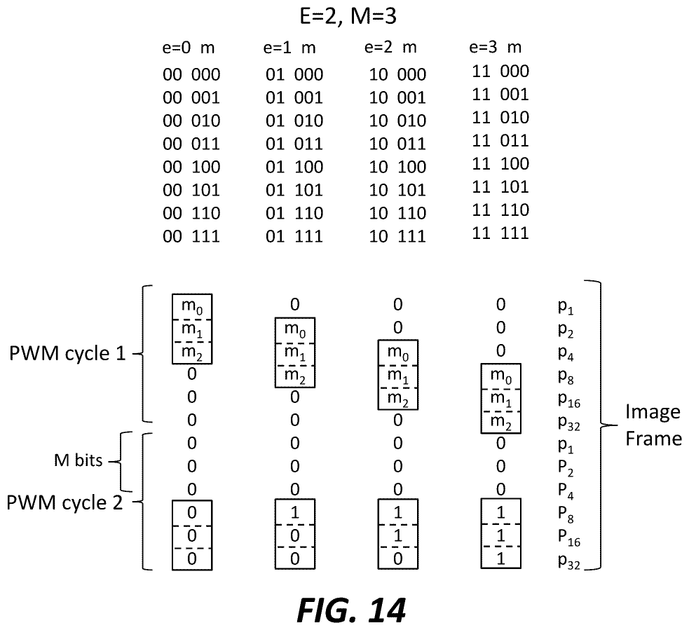

FIG. 13 shows the bit sequence for floating-point pixel values 11 having an exponent e with two bits (E=2) and a mantissa m of three bits M=3). FIG. 14 shows the equivalent bit output sequence for the mantissa in PWM period one and the offset in PWM period two.

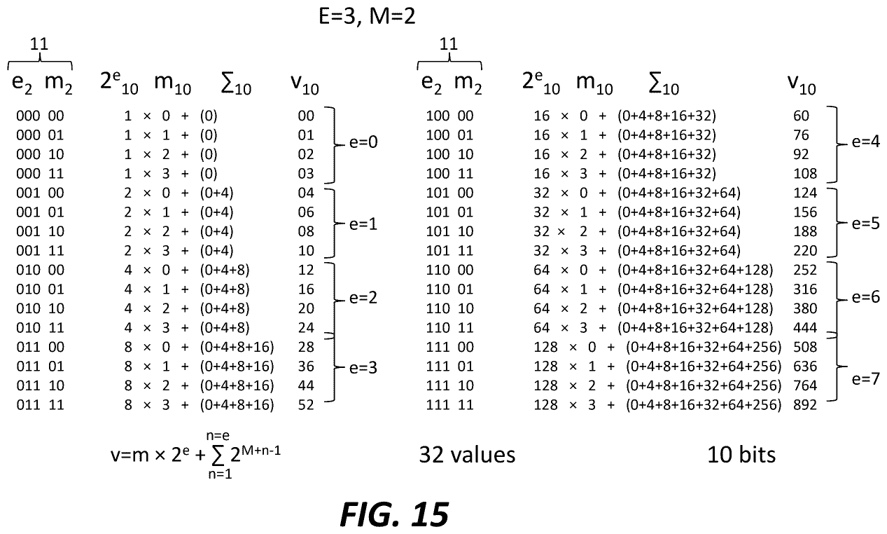

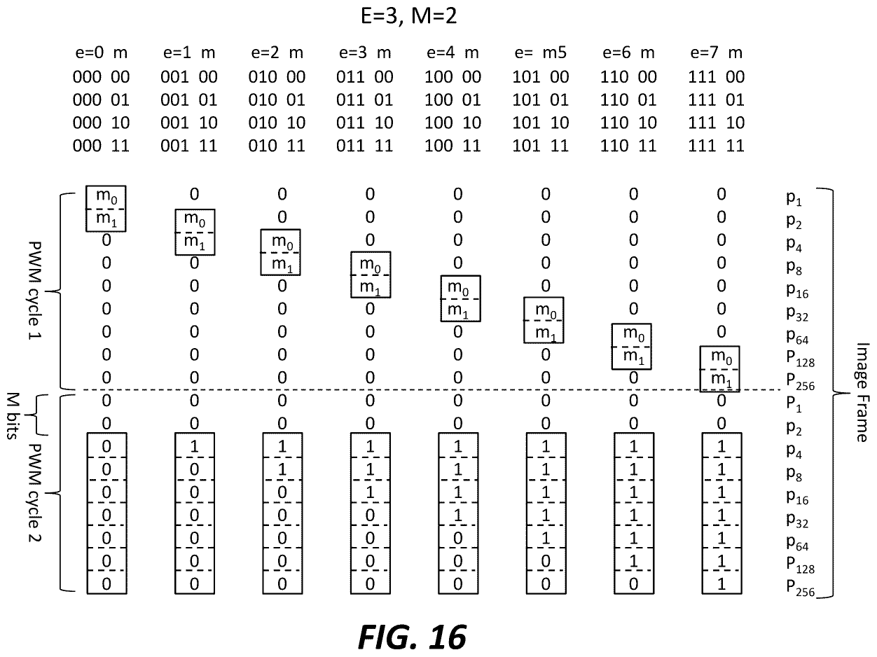

FIG. 15 shows the bit sequence for floating-point pixel values 11 having an exponent e with three bits (E=3) and a mantissa m of two bits M=2). FIG. 16 shows the equivalent bit output sequence for the mantissa in PWM period one and the offset in PWM period two.

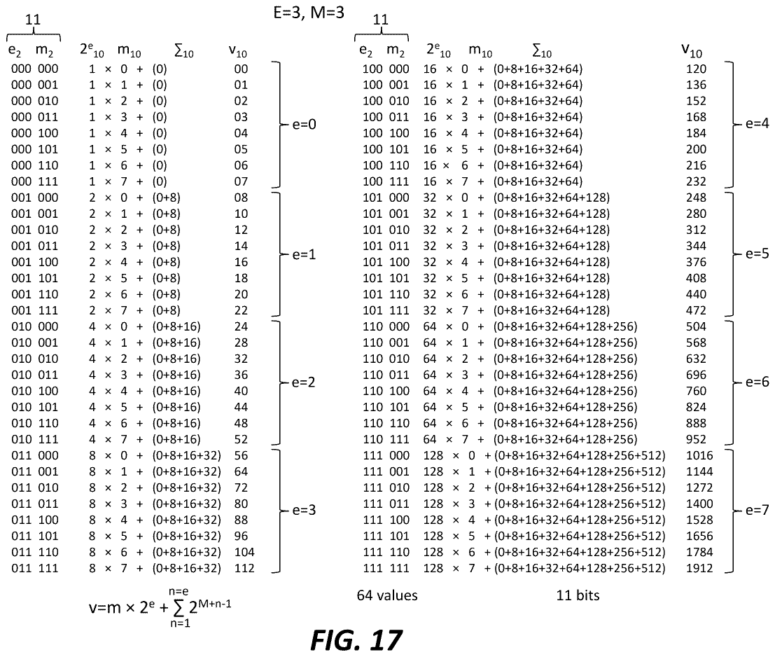

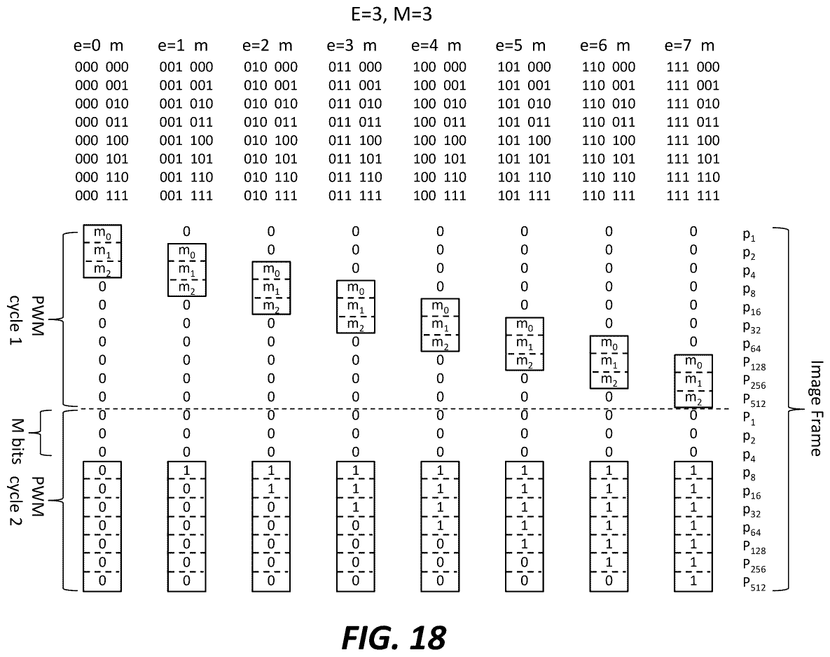

FIG. 17 shows the bit sequence for floating-point pixel values 11 having an exponent e with two bits (E=3) and a mantissa m of three bits M=3). FIG. 18 shows the equivalent bit output sequence for the mantissa in PWM period one and the offset in PWM period two. Thus, in embodiments the number of bits E in the exponent can the same as, larger than, or smaller than the number of bit M in the mantissa.

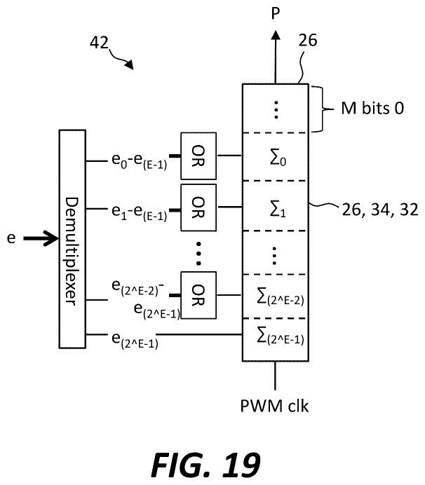

The bits of the mantissa (shifted according to the value of exponent e) can be output during the first PWM period using circuits such as is illustrated in FIG. 5. In some embodiments, the bits of the offset output during the second PWM period can be output using a circuit such as that of FIG. 19. As shown in FIG. 19, the bits of an offset value sigma are formed and stored in offset shift register 34 or mantissa shift register 32 can be reused. The first M bits are set at zero and the remainder are constructed from a demultiplexer that provides a signal for each possible value of e. If the value of e is greater than zero, the first bit of the offset value is set to one. If the value of e is greater than one, the second bit of the offset value is also set to one, and so on. The resulting offset value can then be shifted out using the PWM clock to provide the second PWM signal.

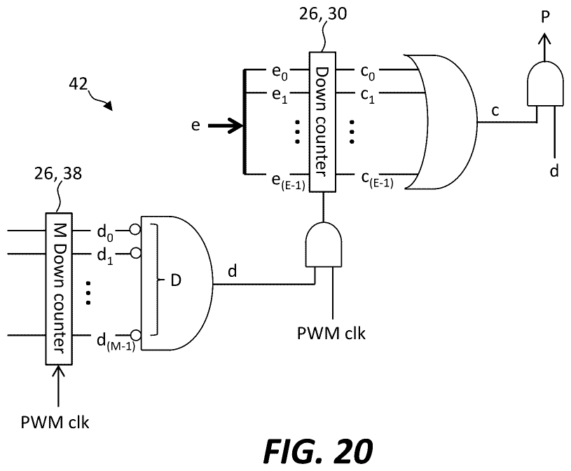

FIG. 20 illustrates embodiments in which the offset value is not completely constructed at a single time (reducing pixel memory 26 size) and the output bits are generated for each PWM clock period. As shown in FIG. 20, the first M bits are counted (e.g., with an M counter 38 comprised in pixel memory 26) and the output set to zero for the count by disabling the PWM clock for the next stage. After the M count in M counter 38 is complete, the PWM clock for the second period is enabled for exponent counter 30. Exponent counter 30 can be the same as that in FIG. 5. The output of exponent counter 30 is combined with an OR gate to enable the second PWM clock and output the PWM bit periods as long as exponent counter 30 is greater than zero, thus constructing the sequence of offset bits.

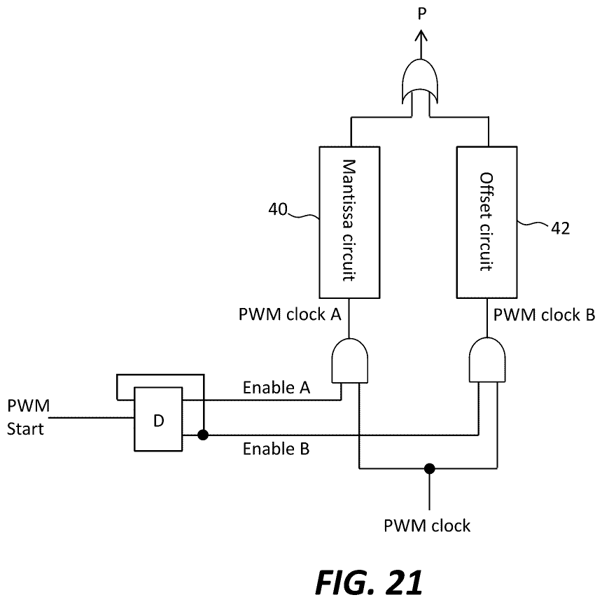

FIG. 21 shows a simplified control circuit (e.g., as part of pixel controller 22) that can alternately select a mantissa circuit 40 (such as in FIG. 5) that outputs bits of mantissa m for a floating-point pixel value 11 and an offset circuit 42 (such as in FIGS. 19 and 20) that outputs bits of offset sigma for floating-point pixel value 11. A shown in FIG. 21, a control signal indicating the beginning of a PWM signal (e.g., the first PWM signal) that is received by a D flipflop to alternately output high (one) or low (zero) signals on opposite enable signals A and B. One of the enable signals (e.g., enable signal A) enables the PWM signal to drive mantissa circuit 40 (e.g., as in FIG. 5) for the first half of an image frame and the other disable offset circuit 42 (as in FIG. 19 or 20) for the second half of the image frame. When the second PWM signal starts, the states of the enable signals A and B reverse and the other (e.g., enable signal B) enables the PWM sign to drive offset circuit 42 and disable mantissa circuit 40. The outputs of the mantissa and offset circuits 40, 42 are combined with an OR signal to form the pulse signal P that constitutes the first and second PWM signals (corresponding toe the mantissa signal and the offset signal.)

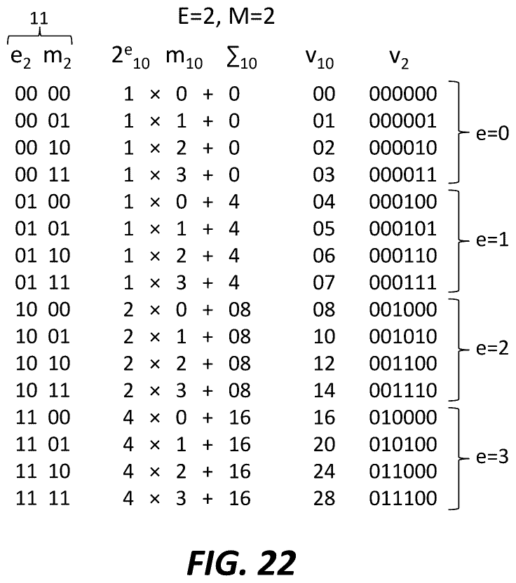

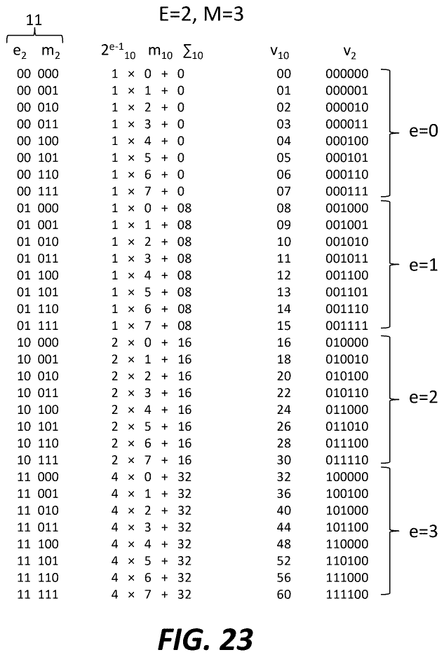

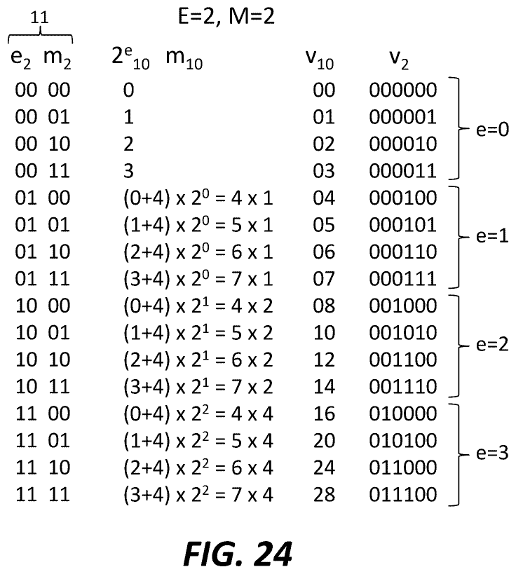

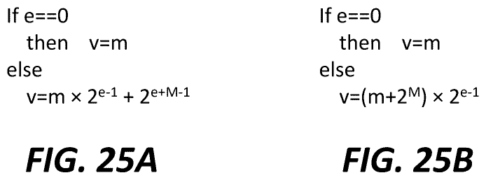

The transformation defined by the equations of FIGS. 8A to 8C and shown in FIGS. 7, 13, 15, and 17 is not the only possible conversion of a floating-point pixel value 11 to a pulse-width modulation signal providing a luminance output with light controller 28. FIGS. 22-24 illustrate a transformation with reduced step changes for a floating-point pixel value 11 when the exponent is one, thus providing an increased number of luminance values for small floating-point pixel values 11 (e.g., for dim or dark image pixels). In such an embodiment, the slopes of the linear functions corresponding to the first two PWM period are the same. FIGS. 22 and 23 illustrate a computation with an offset for such a transformation for E=M=2 and E=2 M=3, respectively. FIG. 24 shows a different computation for the same transformation for floating-point pixel values 11 with two exponent e bits (E=2) and two mantissa m bits (M=2). FIG. 25A is a pseudo-code specification of the transformation computation with an offset for non-zero values of e as m×2^{e-1}+2^{e+M-1} as illustrated in FIGS. 22 and 23. FIG. 25B is a pseudo-code specification of the transformation without an offset for non-zero values of e as (m+2^{M})×2^{e-1} as illustrated in FIG. 24. FIGS. 25A and 25B specify the same transformation using different equations and computation. In both cases, if e is zero, the output v is equal to m. If e is not zero, the output v is as shown in FIGS. 25A and 25B. Other transformations from a floating-point pixel value 11 to a non-linear luminance output by light controller 28 are possible and are included herein.

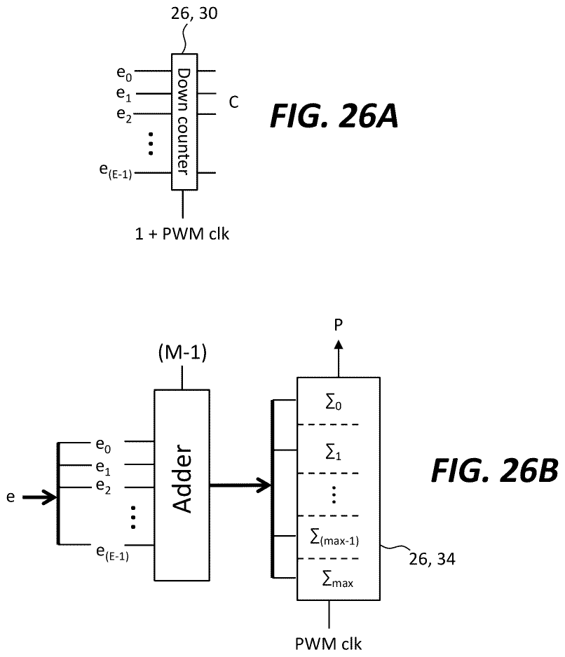

FIG. 26A is a simplified schematic circuit diagram illustrating a circuit that modifies the input to an exponent counter 30 according to the transformation illustrated in FIGS. 22-25B. As shown in FIG. 26A, exponent counter 30 is decremented by one before outputting the mantissa m bits using the PWM clock, thus effectively computing (e−1). The result can be applied as in FIG. 5 to output m×2^{e-1}. FIG. 26B is a simplified schematic circuit diagram for the offset value corresponding to FIGS. 22, 23, and 25A and comprises an adder to calculate e+M−1 for the offset and an offset shift register 34 responsive to the PWM clock to provide the second PWM signal bits. The same pixel memory 26 and shift registers can be used for both computations, since the two computations can be output in separate PWM cycles as in FIG. 21.

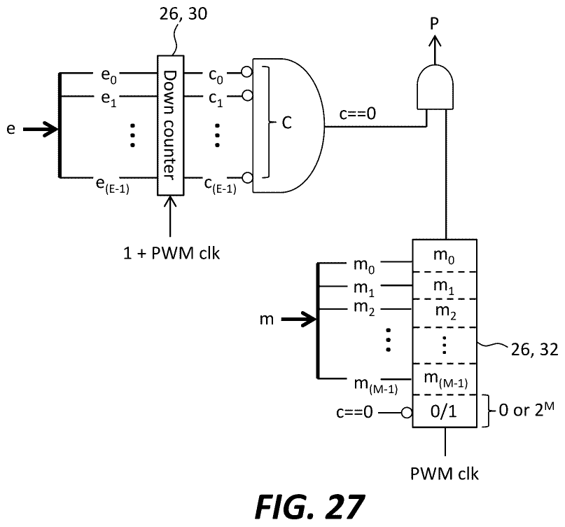

FIG. 27 illustrates a simplified schematic circuit for implementing the equation of FIG. 25B and the table of FIG. 24. As shown in FIG. 27, exponent counter 30 of pixel memory 26 for shifting the mantissa in coordination with the PWM clock is similar to that of FIG. 26A implemented as part of the larger circuit of FIG. 5. Mantissa shift register 32 for outputting the mantissa value includes an extra bit for the offset that is zero if e (and consequently c) is zero and 1 otherwise. Mantissa value m and the extra offset bit can be loaded into mantissa shift register 32 before the PWM clock begins operation, just as exponent e can be loaded into exponent counter 30 and shifted by one before the PWM clock begins operation. (Control and timing circuitry and signals are not included herein to simplify the circuit diagrams, enhance the clarity of the figures, and improve understanding.) This circuit design can be applied to a single PWM cycle associated with an image frame and does not require first and second PWM cycles in an image frame (e.g., does not require a circuit such as FIG. 21).

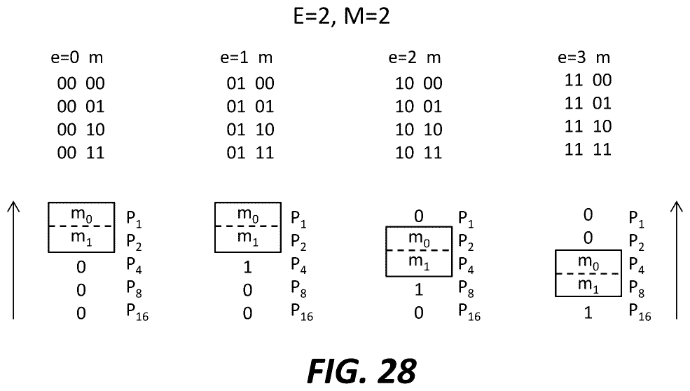

FIGS. 26A, 26B, and 27 provide a circuit in which a fixed-point representation of floating-point pixel value 11 is never generated (and consequently a memory to store the fixed-point pixel value is not required, reducing the memory requirements for pixel controller 22 and pixel memory 26). For example, the storage required can equal E+M+1. FIG. 28 visually illustrates the output of the PWM bits in correspondence with the PWM pulse periods for each of exponent values 0, 1, 2, and 3 in the circuit of FIG. 27. Pixel memory 26 can store the M bits of mantissa m (in this case two bits) that are shifted out in the direction shown by the arrow over time from mantissa shift register 32 in correspondence with the indicated pulse period having a relative temporal length corresponding to the subscript. When e is zero, the M bits are shifted out with the first two pulse periods P₁ and P₂ having relative temporal period lengths of one and two. When e is one, exponent counter 30 also counts zero (e.g., doesn't count because exponent counter 30 was decremented before the PWM process began, as shown in FIG. 27) and the M+1 bits are shifted out with the first two pulse periods P₁ and P₂ having relative temporal period lengths of one and two. The M+1 bit corresponds to the addition of 2^{M} to m in FIG. 25B. Because an M+1 bit is set (as shown in FIG. 27) the set bit is output with a relative temporal period length of four. If e is two, e is decremented to one and pulse period P having a relative temporal period length of one is output as zero followed by the bits of mantissa m with pulse periods two and four and the set bit with pulse period eight. If e is three, e is decremented to two and pulse periods P having relative temporal period lengths of one and two are output as zero followed by the bits of mantissa m with pulse periods four and eight and the set bit with pulse period sixteen.

In pulse-width modulated display embodiments having floating-point pixel values 11 with many bits (to provide a smooth gray scale) and a high frame rate (to provide apparently smooth motion for video sequences), the minimum pulse period length (p₁) can be short (e.g., less than one micro-second or even a few or tens of nano-seconds) and circuits that can provide such short temporal signals can be difficult or expensive to construct. In some embodiments of the present disclosure, driver circuits can drive light controllers 28 with less power (e.g., less current or voltage) for a PWM period so that light controllers 28 emit less light during the PWM period, just as they would with a shorter PWM period. However, if light controllers 28 are driven with a desired (e.g., optimum) efficiency during some periods, driving light controllers 28 with less power during other temporal periods can reduce light controller 28 and floating-point display 10 efficiency during those periods. Thus, in embodiments of the present disclosure using PWM circuits, temporal PWM periods using less power or a less-efficient drive are preferably shorter periods (for less time) corresponding to low-place-value pixel values than temporal PWM periods corresponding to high-place-value pixel values operated at a more desirably optimal efficiency. The use of power bits is also disclosed in U.S. patent application Ser. No. 17/822,962 and its relevant contents are incorporated herein in their entirety.

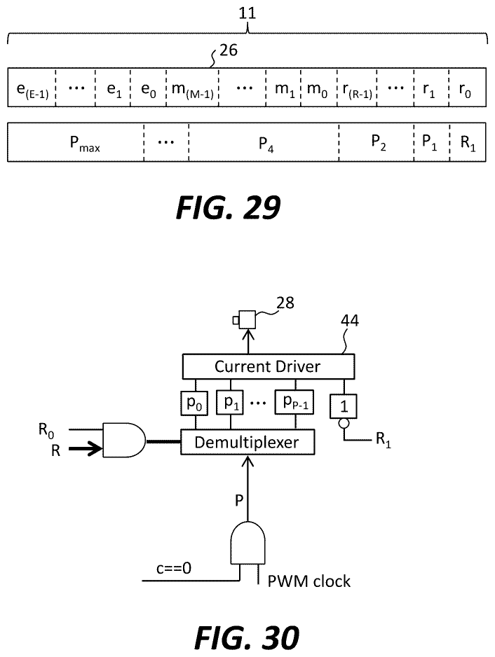

FIG. 29 illustrates a floating-point pixel value 11 that comprises E exponent bits e, M mantissa bits m, and R power bits r. The R power bits r specify the relative brightness of light-controllers 28 during an initial minimum-temporal-length period (e.g., R₁) that is temporally followed by a PWM sequence as described herein. For example, if R=2, r₀ can indicate zero luminance, r₁ can indicate one-quarter luminance, r₂ can indicate one-half luminance, and r₃ can indicate three-quarter luminance. During the initial R₁ period, light controller 28 is controlled to output light according to the value of P (e.g., 0, ¼, ½, or ¾. Thereafter, light controller 28 outputs light at the usual luminance during the subsequent PWM periods (e.g., beginning with P₁).

FIG. 30 is a simplified schematic diagram showing a driver 44 (e.g., a driver for light controller 28 such as a current, voltage, or power driver) operable to provide 2^{P}+1 outputs (including zero) responsive to input values determined from the value of P and period Ro. In this diagram, if R₁ is true (first minimum period), driver 44 controls light controller 28 to emit light according to the value of P. If R₁ is not true (second minimum period and remainder of PWM temporal periods), driver 44 controls light controller 28 to emit light at the usual full designed luminance.

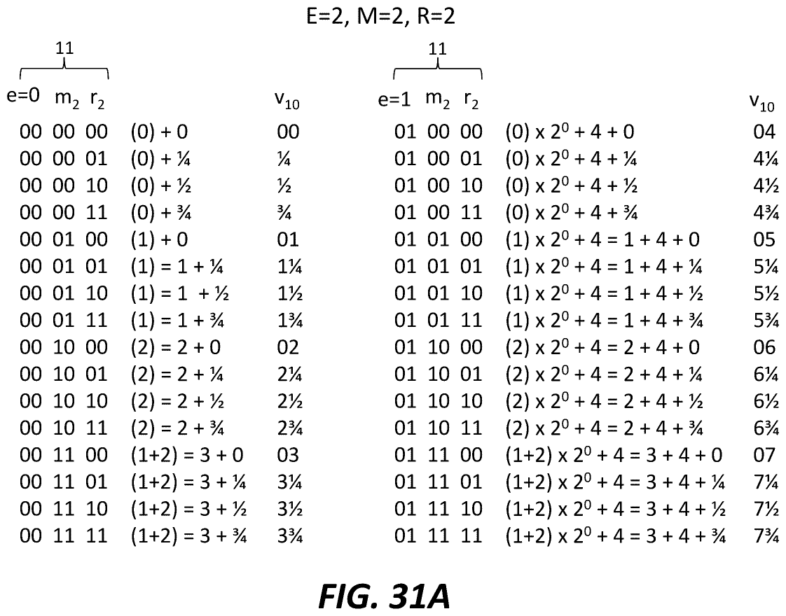

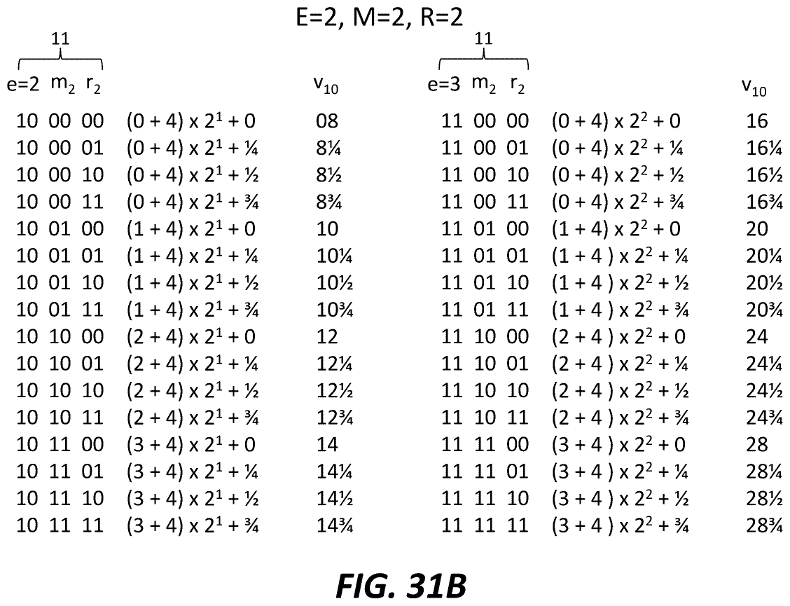

FIGS. 31A and 31B illustrate the effective relative luminance for floating-point pixel value 11 of FIG. 29 for each possible input combination (corresponding to the transformation equation 25B with two power bits r). At low luminance (e.g., e equals zero or one, FIG. 31A), the luminance increments can be controlled by an amount corresponding to po in combination with m and can increase in consistent and uniform increments. At greater luminances (e.g., e greater than one, FIG. 31B), the added luminance provided during the additional R₁ power period is not uniformly increasing and is increasingly unnecessary as, at greater luminances, the human visual system cannot perceive such small changes. Thus, in some embodiments, for e>1, luminance output during the initial minimum period R₁ can be set to zero (e.g., for the outputs shown in FIG. 31B) and the power bits r can be ignored or set to zero, resulting in the right-hand two columns of FIG. 28.

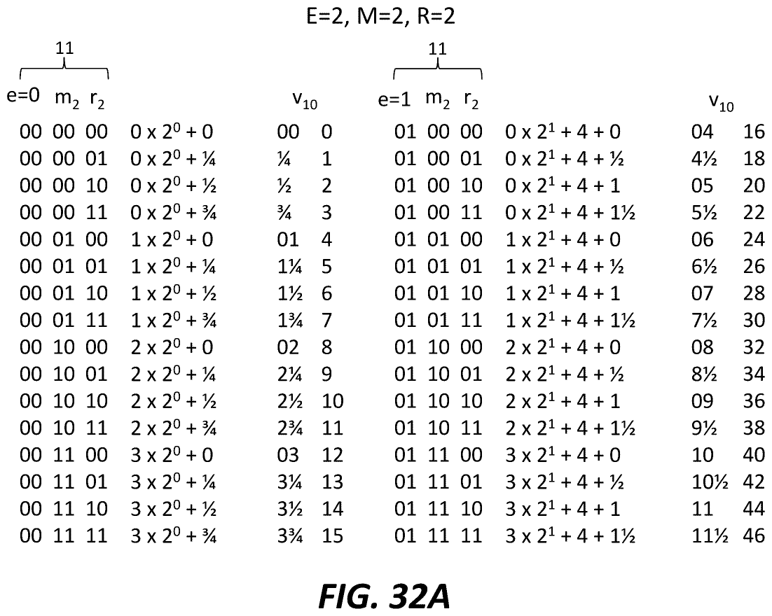

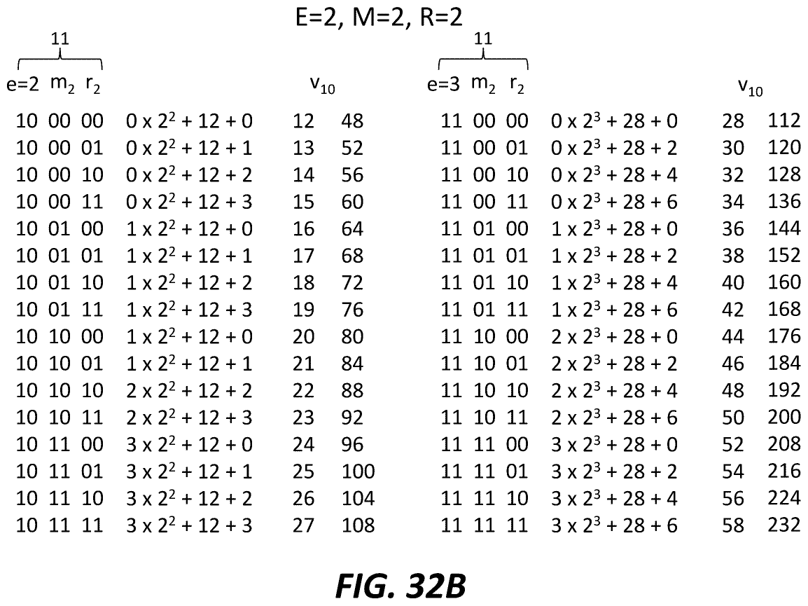

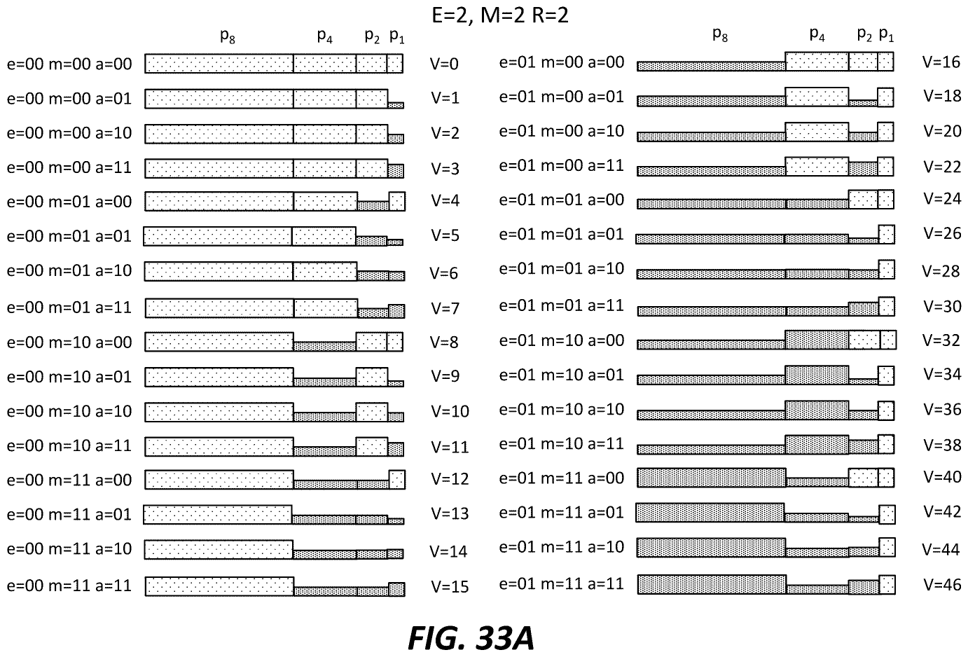

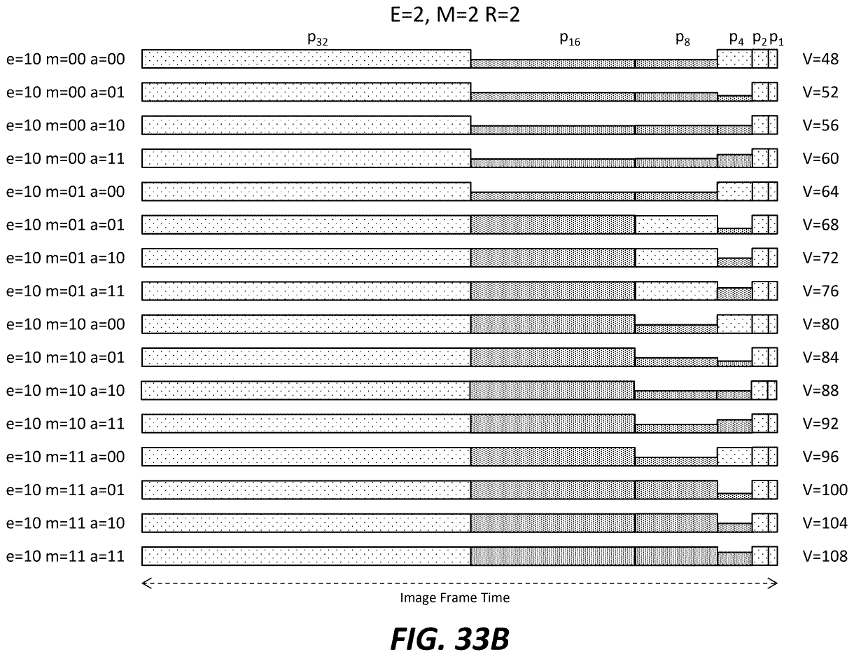

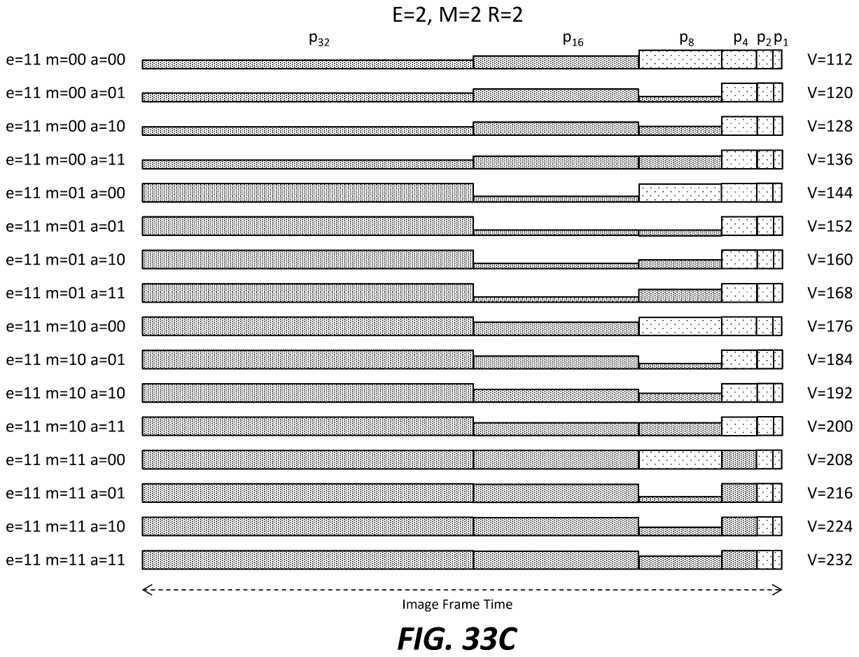

In some embodiments, as shown in FIGS. 32A, 32B, 33A, 33B, and 33C, an additional period to output the power bits is not necessary and the power bits r and the mantissa bits m can be combined in a PWM period sequence with PWM periods shifted in temporal length corresponding to the value of e (e.g., for temporal lengths multiplied by 2^{e}. Moreover, the change in increment magnitude for each value of e is likewise scaled (e.g., by factors of two for increasing values of e), unlike the embodiments of FIGS. 31A and 31B and therefore more uniformly distribute the values of floating-point pixel value 11 throughout its range. As shown in the tables of FIGS. 32A and 32B and the PWM period diagrams of FIGS. 33A, 33B, and 33C for an example of E=M=R=2, power bits r are set at relative values of 0, ¼, ½, and ¾, so that power bits r specify 2^{R} different luminance levels, including zero. Together with an output of one for some periods other than that which is used to output power bits r, for some values of floating-point pixel value 11 this design can employ 2^{R}+1 different luminance levels. For periods in which power bits r are output, the luminance specified can be 0, ¼, ½, and ¾ (in this example). For a period having a relative temporal length of one (e.g., the shortest PWM period), where e equals zero the luminance specified by values of r are the same 0, ¼, ½, and ¾. The mantissa bits m are then specified in periods having greater temporal lengths (multiplied by two for each bit place of mantissa m) and therefore, when providing a luminance of one, are set at a power level of ½ for a period having twice the temporal duration (because two×½ equals one). Hence, not only power bits r can be output at a variety of power levels, mantissa bits m can be as well, as shown in FIGS. 33A-33C, showing the periods and power levels corresponding to floating-point pixel values 11 of the table in FIGS. 32A, 32B. For convenience and ease of discussion, the PWM period diagrams (FIGS. 33A-33C) use whole numbers for the power levels, corresponding to the second column of values V in FIGS. 32A, 32B (multiplying the power levels by 4 from the first column). Thus, both power bits r and mantissa bits m can be output to specify relative luminance levels less than one so that the total darkened area of the PWM periods in a floating-point pixel value 11 represents the value of floating-point pixel value 11.

As shown in FIGS. 32A-33C, the output values v for each value of e increase by ¼ (or one) where e equals 0 because power bit r is output for the minimum PWM period. Output values v for each value of e increase by ½ (or two) where e equals 1 because power bit r is output for twice the minimum PWM period at the same power level. Output values v for each value of e increase by 1 (or four) where e equals 2 because power bit r is output for twice the minimum PWM period. Output values v for each value of e increase by 2 (or eight) where e equals 3 because power bit r is output for four times the minimum PWM period. Similarly, bits of mantissa m are scaled to increasing values by a corresponding increase in PWM period temporal length. In such embodiments, power bits r are output for the minimum PWM period and the mantissa m bits are output for corresponding PWM period lengths according to the number of mantissa m bits. In this example, M=2 so that the two PWM periods greater than the minimum are used to represent the mantissa bits at power levels corresponding to the value of each mantissa bit for the indicated PWM duration (e.g., two and four). For increasing values of e, the PWM periods to which the power bits and the mantissa bits are applied are simply shifted left (e.g., increased in value by powers of two by applying the values to PWM periods that are factors of two greater).

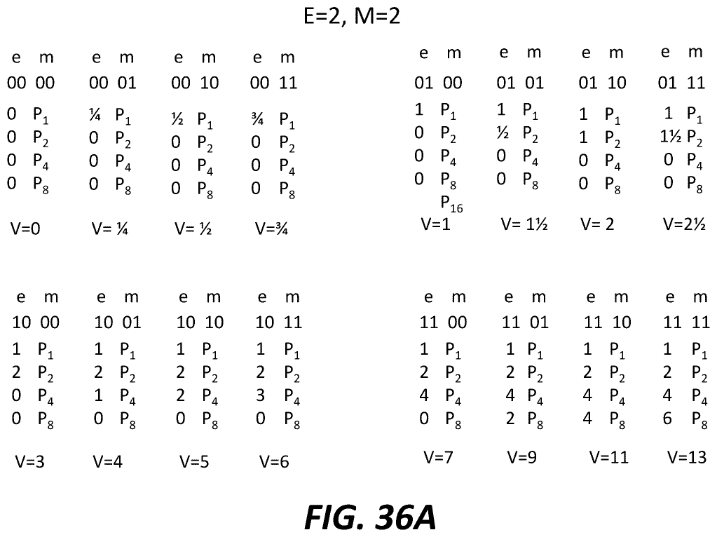

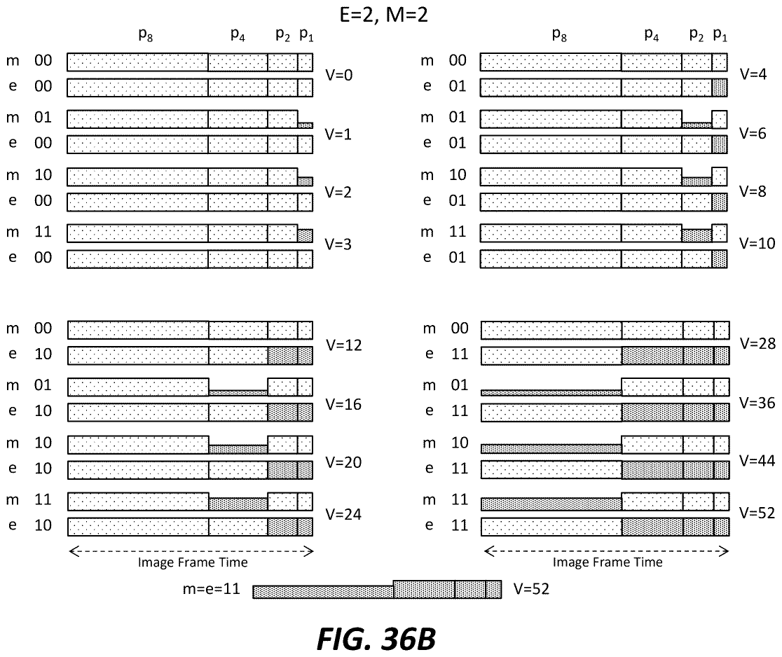

The offset values in such embodiments are derived from the value of e and are applied to other PWM periods than those PWM periods used for the power and mantissa bits. As shown in FIGS. 33A-33C, the offset value can be output by using various power levels for the other PWM periods. Different combinations of power levels and PWM period durations can be used to match the desired offset value; the illustrations in FIGS. 33A-33C are simply one example. FIG. 33A shows the PWM periods and power levels for the cases where e equals zero (left side of FIG. 33A) and e equals one (right side of FIG. 33A). FIG. 33B shows the PWM periods and power levels for the case where e equals two. FIG. 33C shows the PWM periods and power levels for the case where e equals three. FIG. 33A excludes the longer PWM periods for convenience and concise illustration, but they are present in an actual implementation. In FIGS. 33A-33C (and in FIG. 36B below), a lightly dotted rectangle represents a zero output during the corresponding PWM period, a darker rectangle represents a one output for the PWM period. Where the rectangle representing a PWM period has a lower height than the maximum (one), the relative height indicates the relative power level (0, ¼, ½, ¾). All of the PWM periods taken together in one floating-point pixel value 11 can have a temporal length equal to one image frame period.

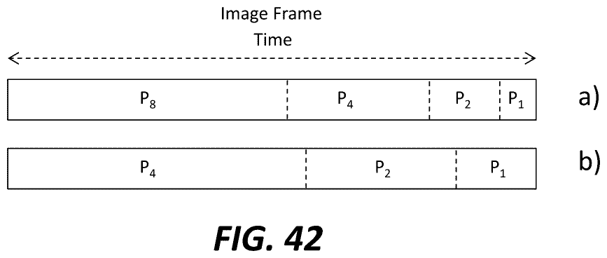

As shown in FIGS. 32A-33C, the number of input bits in the example floating-point pixel value 11 is six and provides a range of up to eight bits (the maximum value of 232<2⁸=256). Thus, the use of two power bits reduces the number of periods into which an image frame time is divided from eight to six, so that the shortest PWM period is 16.7% of the image frame time rather than 12.5% (as discussed below with respect to FIG. 42 with three and four bits), reducing the need for fast electronic circuits and thereby reducing costs or enabling faster image frame rates or greater bit depth for a floating-point pixel value 11. Greater number of power bits r can provide increasing performance advantages (but light controllers 28 such as iLEDs 28 can operate at different power (current) levels that might not be as efficient or can have slightly different colors). Logic circuits necessary to accomplish this (e.g., by adapting the circuit diagrams of FIGS. 5, 9-11, 19-21, 26A-27, and 30) are readily designed. The offset (exponent) and mantissa bits (including the power bits) can be constructed with separate circuits and combined, for example as shown in FIG. 21.

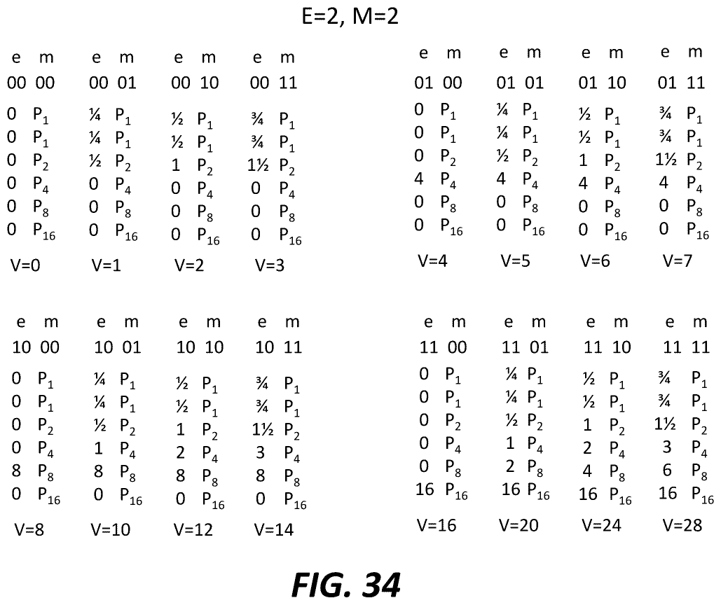

In some embodiments of the present disclosure and as illustrated in FIG. 34, in addition to the initial PWM period R₁, mantissa m specifies the power, and no separate power bits R are used (e.g., the mantissa m bits are the same as power bits r and represent the limit of the approach shown in FIGS. 32A-33C). This could also be understood as having only power r bits and exponent e bits or the mantissa m bits are also power r bits. In such embodiments, a different power level must be provided for each unique value of m and is applied during the PWM periods corresponding to the bit-place of the corresponding bits of mantissa m. The luminance specified by the offset or additional bit following the mantissa (corresponding to the 2^{M} value added to the mantissa in FIG. 25B) is output at full luminance. Logic circuits necessary to accomplish this (e.g., by adapting the circuit diagrams of FIGS. 5, 9-11, 19-21, 26A-27, and 30) are readily designed.

The output of such a control circuit is shown in FIG. 34. FIG. 34 illustrates the successive equivalent luminance values for periods of the PWM clock for each input combination (where E=M=2, thus requiring power outputs of 0, ¼, ½, ¾, and 1). The equivalent output luminance value V (the sum of the bit value times the relative period length) is shown beneath each successive series of luminance values for each input combination (e.g., a sum of the sequentially output luminance values for the corresponding PWM period within an image frame). For example, as shown in the upper left portion of FIG. 34, if E=M=0, v is 0. If e=0 and m=1 then the output power for the M bits is ¼ applied during the initial R₁ period and the two mantissa m bits (multiplied by the PWM period length). If m=2, then the output power for the M bits is ½. If m=3, then the output power for the M bits is ¾. If e=1, the additional bit (multiplied by the PWM period) is added, as shown in the upper right portion of FIG. 34. Mantissa m is not shifted (because e is decremented as shown in FIG. 25B). If e=2, mantissa m and the additional bit are shifted and multiplied by the PWM period as indicated, as shown in the lower left portion of FIG. 34. If e=3, mantissa m and the additional bit are shifted twice and multiplied by the PWM period as indicated, as shown in the lower right portion of FIG. 34.

In this design, one half (the last half) of each non-zero luminance signal operates at a relative efficiency of one and the remainder (the first half) operate at the relative efficiency value specified by the value m, where m₀ can indicate zero luminance, m₁ can indicate one-quarter luminance, m₂ can indicate one-half luminance, and m₃ can indicate three-quarter luminance for M=2.

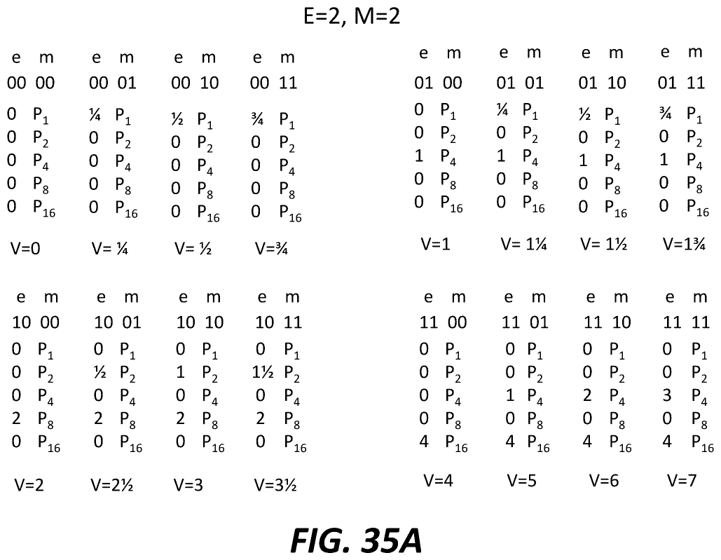

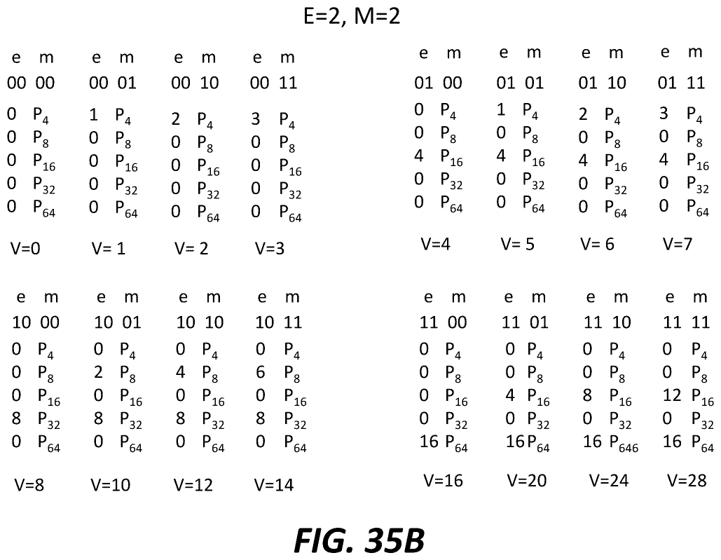

According to some embodiments of the present disclosure, mantissa bits m can be power bits r (e.g., mantissa bits m and power bits r are the same bits) and represent luminance levels that are a relative fraction of one. For example, and as shown in FIGS. 35A and 35B for M and E both equaling two bits, the mantissa m value can equal zero and represent a luminance of zero, m can equal one and represent a relative luminance of ¼, m can equal two and represent a relative luminance of ½, and m can equal three and represent a relative luminance of ¾. These can be output for the shortest PWM period. When e>1, an offset can be added corresponding to the value of e, for example as shown in FIG. 7. For example, a relative luminance of ¼ can be provided during a PWM period corresponding to four (P₄) to provide a relative luminance value of one when e equals 1. A relative luminance of ¼ can be provided during a PWM period corresponding to eight (P₈) to provide a relative luminance value of two when e equals 2. A relative luminance of ¼ can be provided during a PWM period corresponding to sixteen (P₁₆) to provide a relative luminance value of four when e equals 3. This can increase the minimum PWM period length by scaling the value according to the M bits (e.g., four=2^{M} for M=2) as is shown in FIG. 35B. FIG. 35B is identical to FIG. 35A except that the minimum PWM period length is scaled by four. FIGS. 35A and 35B use offsets and apply the mantissa bits to provide the same step differences between mantissa value for e equal to zero and e equal to one.

In alternative embodiments that use relative luminances of one, the offset value corresponding to e can be provided in period shorter than the period in which the mantissa bits are output at M relative luminances less than one (including zero), as shown in FIGS. 36A and 36B for M and E both equaling two bits. FIG. 36A shows the results in tabular form and FIG. 36B shows the equivalent in a PWM period diagram scaling the relative values by four for clarity and ease of understanding. FIGS. 36A and 36B use offsets and apply the mantissa bits to provide the step differences between mantissa values that increase for each value of e, as shown in FIG. 7. As shown in FIGS. 36A and 36B, the mantissa bits are applied to M different power levels corresponding to the value of m for only a single PWM period corresponding to the value of e. When e is zero, the m bits are applied in the shortest PWM period. When e is one, the m bits are applied in the second PWM period, and so forth. At the same time, an offset value corresponding to the value of e is provided by setting all of the periods having a temporal length shorter than the period in which the mantissa bits are applied is set to a relative luminance value of one. The mantissa output period and the offset periods are combined (as shown in the bottom graphic for e=m=3. Thus, in such embodiments the number of PWM periods can 2^{E} and have relative temporal lengths that are uniquely factors of two. Pixel circuit 24 can comprise logic that provides the offset and mantissa period separately and then combines them (or selects the corresponding period) to provide a drive signal to control light emitters 28 (e.g., as shown in FIG. 21).

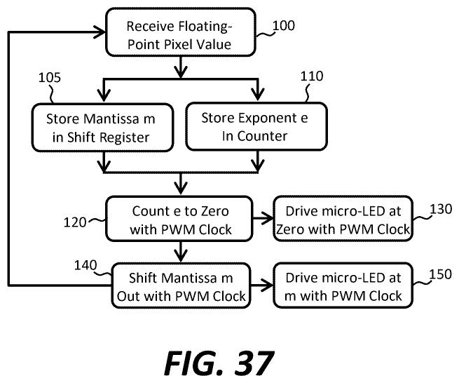

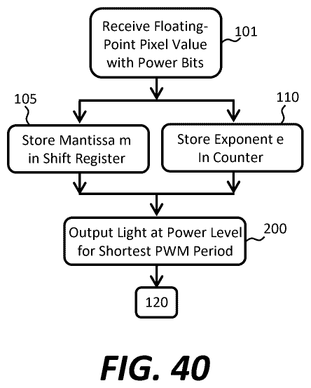

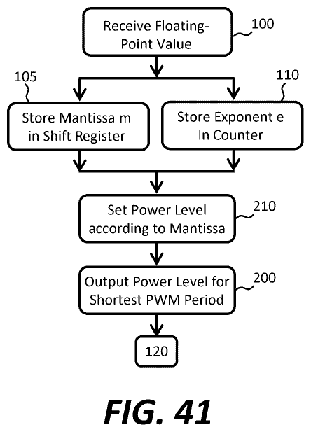

According to embodiments of the present invention and as shown in FIGS. 37-41, a method of operating a floating-point display 10 can comprise providing pixels 20 in the floating-point display 10. Each pixel 20 can comprise a pixel memory 26 for storing a floating-point pixel value 11, a light emitter 28 (e.g., a micro-inorganic light-emitting diode 28), and a pixel circuit 24 operable to control light emitter 28 to emit light corresponding to floating-point pixel value 11. Pixel controller 22 can comprise pixel circuit 24 and pixel memory 26, as well as circuit for controlling light emitter 28, for example iLED 28 driver circuits.

As shown in FIGS. 5 and 37, methods of the present disclosure can comprise receiving a floating-point pixel value 11 comprising a floating-point value having a mantissa m and exponent e for each pixel 20 with pixel circuit 24 in step 100, storing mantissa m in a mantissa shift register 32 in step 105 and storing exponent e in an exponent counter 30 in step 110, counting e down to zero with exponent counter 30 using a PWM clock in step 120 and driving light controller 28 with a zero value for PWM clock periods in step 130 corresponding to the counted PWM clocks in step 120, shifting mantissa m out of mantissa shift register 32 in step 140 in response to each PWM clock subsequent to the counted PWM clocks, and controlling light controller 28 to emit light in response to the mantissa m bits with pixel circuit 24 for temporal periods corresponding to the PWM clock periods subsequent to the counted PWM clock periods in step 150. If a bit of mantissa m is zero, no light is output for the corresponding PWM clock period; if a bit of mantissa m is one, light is output for the corresponding PWM clock period. The process can then begin again with step 100.

As shown in FIGS. 9-11 and 37, methods of the present disclosure can comprise receiving a floating-point pixel value 11 comprising a floating-point value having a mantissa m and exponent e for each pixel 20 with pixel circuit 24 in step 100, storing mantissa m in a mantissa shift register 32 in step 105 and storing exponent e in an exponent counter 30 in step 110, counting e with exponent counter e using a system (not PWM) clock in step 125 and, for each system clock cycle, shifting mantissa m in mantissa shift register 32 in a direction opposite that of step 140 to construct a value equal to m×2^{e} in step 160 and compute an offset in step 165, for example using the circuits shown in FIGS. 9-11. The shifted mantissa and offset values can be added in step 170 to form a fixed-point representation of floating-point pixel value 11 with an offset in a shift register, for example in fixed-point shift register 36. This fixed-point value can be shifted out of fixed-point shift register 36 responsive to the PWM clock (not the system clock) in step 180 to drive micro-LEDs 28 with a PWM signal corresponding to floating-point pixel value 11 in a fixed-point representation. The process can then begin again with step 100.

As shown in FIGS. 27, 28, and 39, methods of the present disclosure can comprise receiving a floating-point pixel value 11 comprising a floating-point value having a mantissa m and exponent e for each pixel 20 with pixel circuit 24 in step 100, storing mantissa m in a mantissa shift register 32 in step 105 and storing exponent e in an exponent counter 30 in step 110, counting (e−1) down to zero with exponent counter 30 using a PWM clock in step 125 and driving iLED 28 with a zero value for PWM clock periods in step 130 corresponding to the counted PWM clocks in step 125, setting the M+1 bit of mantissa shift register 30 in response to value e in step 190, shifting mantissa m out of mantissa shift register 32 in step 140 in response to each PWM clock subsequent to the counted PWM clocks, and controlling light controller 28 to emit light in response to the mantissa m bits in step 150 with pixel circuit 24 for temporal periods corresponding to the PWM clock periods subsequent to the counted PWM clock periods. If a bit of mantissa m is zero, no light is output for the corresponding PWM clock period; if a bit of mantissa m is one, light is output for the corresponding PWM clock period. The process can then begin again with step 100.

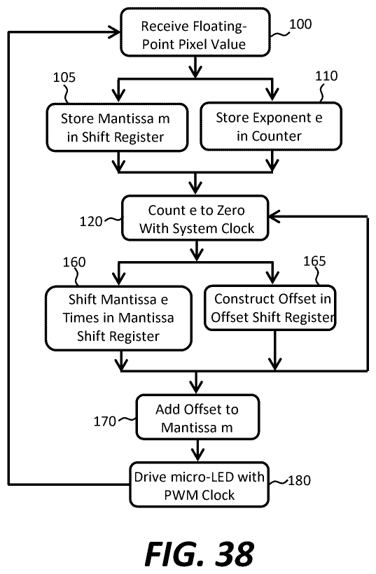

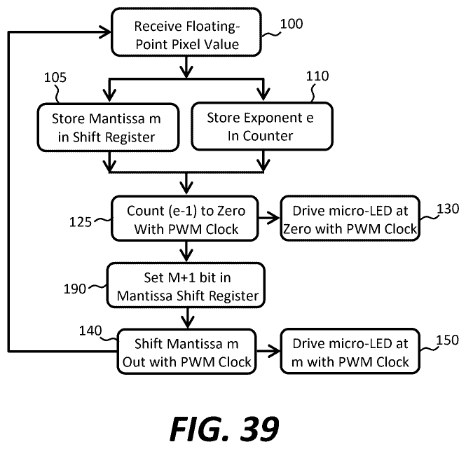

In methods of the present disclosure and as illustrated in FIGS. 29-31B and 40, floating-point pixel value 11 with one or more power bit(s) can be received and stored in step 101 including receiving a floating-point pixel value 11 comprising a floating-point value having a mantissa m and exponent e for each pixel 20 with pixel circuit 24, storing mantissa m in a mantissa shift register 32 in step 105 and storing exponent e in an exponent counter 30 in step 110 and, in step 200, under the control of pixel circuit 24 light-controllers 28 can emit light at a luminance corresponding to the value of the power bits for a time equal to one of two shortest temporal PWM periods. After light corresponding to the power bits is output, the floating-point portion of floating-point pixel value 11 can be output as shown in FIG. 37 or 38 beginning with step 120 or as shown in FIG. 39 with step 125.

In methods of the present disclosure and as illustrated in FIGS. 30, 34, and 41, floating-point pixel value 11 with one or more power bit(s) can be received and stored in step 101 including receiving a floating-point pixel value 11 comprising a floating-point value having a mantissa m and exponent e for each pixel 20 with pixel circuit 24, storing mantissa m in a mantissa shift register 32 in step 105 and storing exponent e in an exponent counter 30 in step 110 and, in step 210, the power level can be set responsive to the power bit(s), for example using a pixel circuit 24 such as that in FIG. 30. In step 200, light-controllers 28 can emit light at a luminance corresponding to the value of the mantissa for a time equal to one of two shortest temporal PWM periods. Subsequently, floating-point pixel value 11 can be output as shown in FIG. 37 or 38 beginning with step 120 or as shown in FIG. 39 with step 125, with the micro-LED 28 luminance specified by the power level bit(s) for all of the PWM periods.

According to embodiments of the present disclosure and as shown in FIG. 1, pixels 20 can comprise multiple light controllers 28 and each pixel circuit 24 of each pixel 20 in floating-point display 10 can control the multiple light controllers 28 (light emitters 28) with separate control signals, for example pixel circuit 24 can control a red light emitter 28R operable to emit red light, a green light emitter 28G operable to emit green light, and a blue light emitter 28B operable to emit blue light. The control signals can be pulse-width modulation signals. The pulse-width modulation signals can be constructed or derived from floating-point pixel values 11, a red floating-point pixel value 11 for red light emitter 28R, a green floating-point pixel value 11 for green light emitter 28G, and a blue floating-point pixel value 11 for blue light emitter 28B. Each of the red, green, and blue light emitters 28R, 28G, 28B, respectively, can be controlled by pixel circuit 24 with corresponding pulse-width-modulation signals derived from corresponding red, green, and blue floating-point pixel values 11. (A floating-point pixel value 11 can refer to or comprise three different floating-point values, one for each of the red, green, and blue light emitters 28 or each of the three different floating-point values can be a separate floating-point pixel value 11.) The three different floating-point pixel values 11 can have different floating-point values and, when used together in a pulse-width modulation system having pulse-width modulation signals, the pulse-width modulation signals can have a common temporal duration and the same or different numbers of periods (e.g., number of bits defining the pulse-width modulation value).

More generally, a pulse-width modulation system can comprise a first component and a second component, a control circuit operable to control the first component with a first pulse-width modulation signal having a first number of periods and operable to control the second component with a second pulse-width modulation signal having a second number of periods. In some embodiments, the first pulse-width modulation signal and the second pulse-width modulation signal have common temporal length, for example corresponding to an image frame in a display such as floating-point display 10, so that every component (or light emitter 28 in a pixel 20) are controlled for a common length (period) of time that can be an image frame.

The human visual system has a greater sensitivity to green light than to red light or blue light. This greater sensitivity means that the human visual system has a greater spatial sensitivity to green light so that green images appear sharper than red or blue images (e.g., red or blue light in a multi-color image). The greater sensitivity to green light also means that the human visual system can detect a greater number of luminance (brightness) levels of green light than for red light or blue light. In other words, the human eye can see (sense) more different shades of green light than shades of red light or shades of blue light. Therefore, red pixel values (e.g., red floating-point pixel values 11), green pixel values (e.g., green floating-point pixel values 11), and blue pixel values (e.g., red floating-point pixel values 11) can be controlled by pixel circuit 24 with different numbers of bits to provide a multi-color pixel 20 having red, green, and blue light emitters 28R, 28G, 28B adapted to the human visual system. The different numbers of bits in different-colored floating-point pixel values can reduce the amount of data communicated to each pixel 20 in floating-point display 10, thereby improving the performance and efficiency of floating-point display 10 without reducing the perceived quality of a multi-color image displayed on floating-point display 10. In particular, red and blue pixel values (e.g., either floating-point pixel values or fixed-point pixel values) can be specified with fewer bits than green pixel values without decreasing perceived image quality in a display.

Thus, in embodiments of the present disclosure, the number of periods in each pulse-width modulation signals supplied to components in a pulse-width modulation system can be different. For example, the number of periods in a green pulse-width modulation signal applied to a green light-emitter 28G in an image frame can be greater than the number of periods in a red pulse-width modulation signal applied to a red light-emitter 28R or a blue pulse-width modulation signal applied to a blue light-emitter 28B in an image period. The components (e.g., red, green, and blue light emitters 28R, 28G, and 28B) can be controlled for the same amount of time (e.g., for an image frame) so that they can have a same luminance range (e.g., off for the entire image frame or on for the entire image frame), but can have a different number of PWM periods within the image frame, so that different numbers of luminance levels (and different luminance levels) can be expressed by pixel values having fewer bits. In a simple example, a green pixel value can comprise eight bits (specifying 256 different luminance levels), and red or blue pixel values can comprise six bits (specifying 64 different luminance levels), reducing the number of bits in a multi-color pixel from 24 (eight bits for each of red, green, and blue sub-pixels 28R, 28G, 28B, respectively) to 20 bits (eight bits for a green sub-pixel 28G and six bits for each of red and blue sub-pixels 28R, 28B, respectively). The bits can specify fixed-point values or floating-point values as described herein. For example, floating-point pixel values 11 can comprise a green floating-point pixel value 11 having a ten-bit mantissa and a six-bit exponent and red and blue floating-point pixel values 11 each having an eight-bit mantissa and a four-bit exponent, reducing a multi-color floating-point pixel value 11 from 48 bits (three times sixteen bits for each of three colors red, green, and blue) to 40 bits (sixteen bits for green and twelve bits for each of red and blue).

FIG. 42 illustrates two different PWM signals that can be applied to two different components in a pulse-width-modulation system (e.g., two different light emitters 28 in a pixel 20 of a pulse-width-modulation display 10). The PWM signal a) in FIG. 42 comprises 4 bits defining four PWM periods having relative lengths of one, two, four, and eight. The PWM signal b) in FIG. 42 comprises 3 bits defining three PWM periods having relative lengths of one, two, and four. The range of each PWM signal is the same. Both are zero if all of the bits in the PWM signal are zero (e.g., off for the entire image frame) and at a maximum (e.g., on for the entire image frame) if all of the bits in the PWM signal are one. However, the PWM signal a) defines 16 different levels (e.g., luminance levels) with four bits and the PWM signal b) defines eight different levels (e.g., luminance levels) with three bits.

In embodiments of the present disclosure, therefore, pixel circuit 24 controls two (or more) different PWM signals, each used to control a different component. The different PWM signals have a common temporal length (e.g., the different PWM signals are used by pixel circuit 24 to output control signals for a common length of time) but have different numbers of periods. The sum of the periods (the total time) of each of the different PWM signals used to control a component such as a light emitter 28 is the same but the periods in (comprising) the different PWM signals can have different temporal lengths, as shown in FIG. 42 where each of P₁, P₂, and P₄ of PWM signal a) is shorter than the corresponding period of PWM signal b). PWM signal a) also has more periods (four) than PWM signal b) (three) since PWM signal b) does not have a P₈ period, as it lacks sufficient bits to define a fourth period. The embodiments of FIG. 42 are illustrative; a more practical implementation of embodiments a) and b) might have, for example, twelve bits and eight bits, or sixteen bits and twelve bits.

Anyone or combination of elements of pixel controller 22 (such as pixel memory 26, pixel circuit 24, and any light-controller 28 driver circuits 44) can all be digital, analog, or mixed-signal circuits provided in one or more integrated circuits (e.g., silicon integrated circuits) and disposed on a display substrate 18 (e.g., as shown in FIG. 1) or on a pixel substrate disposed on a display substrate 18. Pixel controller 22 can be native to a display substrate 18, native to a pixel substrate, or provided in integrated circuits disposed on and non-native to display substrate 18 or a pixel substrate, for example by micro-transfer printing. Light controller 28 can likewise be disposed on a display substrate 18 or on a pixel substrate and can be non-native to either or both. Such integrated circuits can be provided in bare, unpackaged die and micro-transfer printed from source wafers to a desired target substrate (e.g., a display substrate 18 or pixel module substrate) and therefore comprise broken (e.g., fractured) or separated tethers 29. Pixel controller 22 (e.g., pixel memory 26 and pixel circuit 24) can comprise monocrystalline silicon. Similarly, light controllers 28 such as inorganic light-emitting diodes 28 can be transferred from LED source wafers to a desired target substrate (e.g., a display substrate 18 or pixel module substrate) and can also comprise broken (e.g., fractured) or separated tethers 29.

Bare-die integrated circuits disposed on a display substrate 18 (as shown in floating-point display 10 of FIG. 1) or on a pixel module substrate can be electrically connected using photolithographic or printed-circuit board methods and materials. Signals transmitted between integrated circuits or within an integrated circuit and to light controller 28 can be electrically conductive patterned thin-film metal electrical interconnects or wires (e.g., metal wires) or light pipes photolithographically defined on a display substrate 18, pixel substrate, or in integrated circuits. Power and ground signals can be provided on wires to pixel controller 22 or light controller 28 (not shown in the Figures) to operate pixel controller 22 and light controller 28.

Floating-point display 10 can be a multi-color display with multiple different light controllers 28, for example red inorganic light-emitting diodes 28R that emit red light, green inorganic light-emitting diodes 28G that emit green light, and blue inorganic light-emitting diodes 28B that emit blue light. Pulse-width-modulation pulses P can be digital signals, for example a binary weighted digital signal and can comprise pixel data for each color of light emitted by pixels 20, for example red, green and blue light emitted by corresponding the red, green, and blue light controllers 28. A single pixel controller 22 can control all of the different inorganic light-emitting diodes that emit different colors of light in pixel 20 using floating-point pixel values 11 for each color of light controller 28 to provide power (e.g., current or voltage) signals to each light controller 28 using pulse-width-modulation iLEDs 28. In some embodiments, a separate pixel controller 22 comprising pixel circuit 24, and pixel memory 26 is provided for each different color of light controller 28.

Light controllers 28 can be light-emitting diodes (e.g., inorganic light emitting diodes 28 such as micro-transfer printed micro-inorganic-light-emitting diode or organic light-emitting diodes) that can switch very rapidly between an on-state and an off-state (e.g., within a few micro-seconds, one micro-second, or less than a micro-second) in response to a digital control signal such as pulse periods in a pulse-width modulation signal (e.g., either on at a fixed voltage and constant current emitting light or off and not emitting light at, for example, zero volts). The human visual system averages the light emitted during the minimum pulse width time period in each display image frame to perceive an average brightness during the display frame if the pulses are sufficiently fast and short. In contrast, light emitters in displays driven by a variable voltage or variable current displays are on for the entire display frame but at a brightness dependent on the voltage or current supplied to the light emitters. Light-emitting diodes can have variable efficiency depending on the voltage or current supplied; thus light-emitting diodes driven at a constant current and voltage for variable amounts of time specified by a temporal pulse-width modulation signal, and according to embodiments of the present disclosure, can be more power efficient by operating at or near peak efficiency during the temporal pulses.

Inorganic light-emitting diodes (iLEDs) 28 can operate most efficiently at a given current. Moreover, different types of iLEDs 28 such as iLEDs 28 that emit different colors of light can operate most efficiently at different constant currents or different voltages and can be driven at different constant currents for variable time periods. When light controller 28 is off, no current flows to light controller 28. When light controller 28 is on, ideally a constant, unvarying current at a fixed voltage flows to the operational light controller 28 emitting light. According to some embodiments of the present disclosure, a PWM circuit can control each (e.g., respective) light controller 28 in each pixel 20 in an active-matrix floating-point display 10 comprising an array of pixels 20, for example with a different desired constant current and voltage. When operational, light controller 28 emits light at a constant luminance. If light controller 28 is turned on and off quickly, the human visual system cannot perceive the switching and instead perceives a variable brightness depending on the amount of time the light emitter is on at the predetermined constant luminance for an image frame period.

A drive circuit for light controllers 28 can comprise an effectively binary digital switch fed by a constant-current supply because it does not continuously modulate the amount of current supplied by the constant-current supply but rather operates in a first mode in which light controller 28 is turned off (e.g., at a zero voltage) and no current flows through light controller 28 and a second mode in which the current flows through light controller 28 at a designed constant current and non-zero voltage specified by the constant-current supply. The constant amount of current (or voltage) can be selected in response to PWM pulses P and, depending on the circuit design, controlled by a current supply circuit controller or drive circuit. Thus, a constant-current supply circuit can have selectable constant currents that can be selected to provide various different desired constant currents.

Certain embodiments of the present disclosure can be applied to floating-point displays 10. For example, display control signals from display controller 12 can comprise a row-control signal provided on a row wire 14 and a column-data signal provided on a column wire 16 and electrically connected to an array of pixels 20 arranged in rows and columns on a display substrate 18 in an active-matrix floating-point display 10. Each pixel 20 can comprise one or multiple light controllers 28, each of which can comprise, for example, a micro-inorganic-light-emitting diode 28. Each of multiple light controllers 28 in pixel 20 can be or include a different inorganic light-emitting diode 28 that emits a different color of light when provided with electrical current at a suitable voltage.

According to some embodiments of the present disclosure, pixel controller 22 can comprise any of a variety of transistors, for example transistors such as those known in the electronics, integrated circuit, and display industries. Transistors can be thin-film transistors (TFTs), for example amorphous transistors or polysilicon transistors and can be a semiconductor thin-film circuit formed on a substrate, such as a display substrate 18. In some embodiments, transistors are crystalline silicon or compound semiconductor transistors, for example made in an integrated circuit process and can be transfer printed onto a display substrate 18 or onto a pixel module substrate that is transfer printed onto display substrate 18. Such transfer-printed structure can comprise fractured or separated tethers 29.

According to some embodiments of the present disclosure, light controllers 28 are micro-inorganic-light-emitting diodes 28 (micro-iLEDs) with at least one of a width and a length that is no greater than 500 microns (e.g., no greater than 200 microns, no greater than 100 microns, no greater than 50 microns, no greater than 25 microns, no greater than 15 microns, no greater than 12 microns, no greater than 8 microns, or no greater than 5 microns). Micro-LEDs provide an advantage according to some embodiments of the present disclosure since they are sufficiently small and can be disposed spatially close together so that the different micro-LEDs in pixel 20 cannot be readily distinguished by the human visual system in a display at a desired viewing distance, improving color mixing of light emitted by pixel 20 and providing apparent improvements in display resolution. The use of high-performance micro-transfer-printed pixel controllers 22 can enable the use of floating-point pixel values 11 that reduce the amount of pixel data that is communicated over display substrate 18 to pixels 20 and thereby increasing the performance of floating-point display 10, such as increased size, increased number of pixels 20, and decreased power consumption. For example, embodiments of the present disclosure can reduce data bandwidth by up to a factor of two or three. Embodiments of the present disclosure can be constructed using micro-transfer printing.

Methods of forming useful micro-transfer printable structures are described, for example, in the paper AMOLED Displays using Transfer-Printed Integrated Circuits, Journal of the SID, 19(4), 2012, and U.S. Pat. No. 8,889,485. For a discussion of micro-transfer printing techniques see, U.S. Pat. Nos. 8,722,458, 7,622,367 and 8,506,867, the disclosures of which are hereby incorporated by reference in their entirety. Micro-transfer printing using compound micro-assembly structures and methods can also be used with the present disclosure, for example, as described in U.S. patent application Ser. No. 14/822,868, filed Aug. 10, 2015, entitled Compound Micro-Assembly Strategies and Devices, the disclosure of which is hereby incorporated by reference in its entirety. In some embodiments, pixels 20 are compound micro-assembled devices.

As is understood by those skilled in the art, the terms “over” and “under”, “above” and “below”, and “top” and “bottom” are relative terms and can be interchanged in reference to different orientations of the layers, elements, and substrates included in the present invention. For example, a first layer on a second layer, in some implementations means a first layer directly on and in contact with a second layer. In other implementations a first layer on a second layer includes a first layer and a second layer with another layer therebetween.

Throughout the description, where apparatus and systems are described as having, including, or comprising specific components, or where processes and methods are described as having, including, or comprising specific steps, it is contemplated that, additionally, there are apparatus, and systems of the disclosed technology that consist essentially of, or consist of, the recited components, and that there are processes and methods according to the disclosed technology that consist essentially of, or consist of, the recited processing steps.

It should be understood that the order of steps or order for performing certain action is immaterial so long as operability is maintained. Moreover, two or more steps or actions in some circumstances can be conducted simultaneously.

Having expressly described certain embodiments, it will now become apparent to one skilled in the art that other embodiments incorporating the concepts of the disclosure may be used. Therefore, the claimed invention should not be limited to the described embodiments but rather should be limited only by the spirit and scope of the following claims.

### PARTS LIST

c count
e exponent
E number of exponent bits
m mantissa
M number of mantissa bits
p pulse-width modulation period
P pulse-width modulation signal
r power bit
R number of power bits
v bit of fixed-point pixel value/value
V fixed-point pixel value/fixed-point value/value
10 floating-point display
11 floating-point pixel value
12 display controller
12C column controller
12D display interface
12R row controller
14 row wire
16 column wire
18 display substrate
20 pixel
21 pixel wires
22 pixel controller
24 pixel circuit
26 pixel memory
28 iLED/light controller/light emitter
28R red iLED
28G green iLED
28B blue iLED
29 tether
30 exponent counter
32 mantissa shift register
34 offset shift register
36 fixed-point shift register
38 M counter
40 mantissa circuit
42 offset circuit
44 driver/driver circuit/driver-control circuit
100 receive floating-point pixel value with power bit step
101 receive floating-point pixel value step
105 store mantissa m in shift register step
110 store exponent e in counter step
120 count e to zero with PWM clock step
125 count e−1 to zero with PWM clock step
130 drive micro-LED at zero with PWM clock step
140 shift mantissa m out with PWM clock step
150 drive micro-LED at m with PWM clock step
160 shift mantissa e times in mantissa shift register step
165 construct offset in offset shift register step
170 construct offset in offset shift register step
180 drive micro-LED at m with PWM clock step
190 set M+1 bit in mantissa shift register step
200 output light at power level for shortest PWM period step
210 set power level according to mantissa step

1. A floating-point display, comprising:
a plurality of pixels, each pixel comprising a pixel memory for storing a floating-point pixel value v, one or more light emitters, and a pixel circuit operable to control the one or more light emitters to emit light corresponding to the floating-point pixel value v,
wherein for each of the plurality of pixels the floating-point pixel value v is or comprises a floating-point value.

2. The floating-point display of claim 1, wherein the floating-point pixel value v is a binary value and the pixel memory is operable to store the binary value.

3. (canceled)

4. The floating-point display of claim 1, wherein the floating-point pixel value v comprises a mantissa m and an exponent e and wherein the floating-point pixel value v either:
equals m×2^{e} or is derived from m×2^{e},
equals m×2^{e} plus an offset value or is derived from m×2^{e} plus an offset value,
equals (m+k)×2^{(e+j)} or is derived from (m+k)×2^{(e+j)}, or
equals (m+k)×2^{(e+j)} plus an offset value or is derived from (m+k)×2^{(e+j)} plus an offset value,
where j and k are constants.

5. The floating-point display of claim 4, wherein the offset value:
(i) equals (2^{e}−1)×4,
(ii) equals 2^{(e+2)}−4,
(iii) equals the sum of all values equal to 2⁽ⁿ⁺¹⁾ or is derived from or is a combination of the values equal to 2⁽ⁿ⁺¹⁾, wherein n ranges from one to e, and if e is zero then the sum is zero.

6-10. (canceled)

11. The floating-point display of claim 1, wherein the floating-point pixel value v comprises a mantissa m having M bits and an exponent e having E bits and wherein the pixel circuit comprises one or more sequentially accessible memories operable to output sequential bits representing a value of (i) m×2^{e}, (ii) 2^{e}, (iii) 2^{(e+2)}, (iv) (m+k)×2^{e}, (v)(m+k)×2^{e+j}, (vi) 2^{e}, (vii) 2^{e+j}, (viii) 2^{(e+2)}, or (ix) any combination of these or derived or responsive to these, where j and k are constants.

12. The floating-point display of claim 1, wherein the floating-point pixel value v comprises a mantissa m and an exponent e, and wherein the pixel circuit converts the floating-point pixel value v to a corresponding pulse-width modulation signal (i) using fewer than log₂((2^{M}−1)×2^{(2\hat{ }E-1)}) storage locations or (ii) using fewer than a number of storage locations required to store a maximum possible value of the floating-point pixel value v.

13. The floating-point display of claim 1, wherein the floating-point pixel value v comprises a mantissa m having M bits and an exponent e having E bits and wherein the pixel circuit comprises an accumulator operable to compute the sum of all values equal to 2^{M+(n-1)}, wherein n ranges from one to e, and wherein the sum of all values equal to 2^{M+(n-1)} is zero if e is zero.

14. The floating-point display of claim 1, wherein the pixel circuit comprises a counter responsive to a pulse-width modulation clock.

15. The floating-point display of claim 14, wherein the floating-point pixel value v comprises a mantissa m and an exponent e and wherein the counter is operable to count a value that is the exponent e, a value derived from the exponent e, the exponent e−1, or a value derived from the exponent e−1.

16. The floating-point display of claim 14, wherein the floating-point pixel value v comprises a mantissa m and an exponent e and wherein the counter is operable to count a value that is the number of bits of the mantissa m.

17. The floating-point display of claim 1, wherein the floating-point pixel value v comprises a mantissa m and an exponent e and wherein the mantissa m is a binary value comprising M bits and wherein the pixel circuit comprises a shift register responsive to a pulse-width modulation circuit that sequentially provides the M bits in an order corresponding to the places of the binary value and each of the M bits is provided for a time period corresponding to time periods of a pulse-width modulation clock or a pulse-width-modulation signal.

18. The floating-point display of claim 1, wherein the floating-point pixel value v comprises a mantissa m and an exponent e, wherein if e is equal to zero then the floating-point pixel value v equals m, and if e does not equal zero then the floating-point pixel value v either (i) equals m×2^{e-1} plus an offset equal to 2^{(e+M-1)}, or (ii) equals (m+2^{M})×2^{e-1}.

19. (canceled)

20. A pulse-width modulation floating-point conversion circuit, wherein the floating-point conversion circuit is configured to:
receive a binary floating-point value comprising bits of a mantissa m and an exponent e; and
output each bit of the mantissa m for a time period corresponding to a pulse-width modulation signal or clock time period.

21. The pulse-width modulation floating-point conversion circuit of claim 20, wherein:
the bits of mantissa m are sequentially output for time periods corresponding to time periods of the pulse-width-modulation signal.

22. The pulse-width modulation floating-point conversion circuit of claim 21, wherein the bits of the mantissa are shifted by the exponent e with respect to corresponding sequential time periods.

23. (canceled)

24. The pulse-width modulation floating-point conversion circuit of claim 20, wherein the floating-point pixel value comprises pulse-width-modulation bits specifying both (i) a floating-point value and (ii) power bits specifying power levels.

25-38. (canceled)

39. A method comprising the steps of:
providing a plurality of pixels in a floating-point display, each pixel comprising a pixel memory for storing a floating-point pixel value, one or more light emitters, and a pixel circuit;
receiving a corresponding floating-point pixel value comprising a floating-point value for each pixel with the pixel circuit; and
controlling the one or more emitters to emit light in response to the floating-point value with the pixel circuit.

40. The method of claim 39, wherein the controlling of the one or more light emitters comprises controlling the one or more light emitters with the pixel circuit to emit the light using pulse-width modulation.

41. The method of claim 40, wherein the floating-point pixel value comprises a mantissa m and an exponent e, wherein the method further comprises converting the floating-point pixel value to a fixed-point pixel value with the pixel circuit by storing the mantissa m in a shift register and shifting the mantissa m in the shift register in response to the exponent e.

42. The method of claim 40, wherein the floating-point pixel value comprises a mantissa m and an exponent e wherein the pixel circuit controls the one or more light emitters to emit the light at a luminance value corresponding to the floating-point pixel value by storing the mantissa m in a shift register and the exponent e in a counter, counting a number of pulse-width-modulation periods with the counter, applying a counted pulse-width-modulation period to a first mantissa bit, and shifting remaining bits of the mantissa out of the shift register in response to a pulse-width-modulation clock comprising subsequent pulse-width-modulation periods.

43. (canceled)

44. The method of claim 39, wherein the floating-point pixel value comprises a mantissa m and an exponent e, wherein the method further comprises:
storing the exponent e in a counter and storing the mantissa m in a shift register;
counting the exponent e with the counter; and
shifting the mantissa m with the shift register.

45-71. (canceled)
